(19) United States
(12) Patent Application Publication
(10) Pub. No.: US 2025/0163793 A1
(43) Pub. Date: May 22, 2025

(54) NON-LINEAR TRAJECTORY OPTIMIZATION TOWARDS AUTOMATED DRILLING APPLICATIONS

(71) Applicant: Halliburton Energy Services, Inc., Houston, TX (US)

(72) Inventors: Omer Burak Iskender, Singapore (SG); Robert P. Darbe, Houston, TX (US); Zhijie Sun, Houston, TX (US)

(21) Appl. No.: 18/511,075

(22) Filed: Nov. 16, 2023

(51) Int. Cl. E21B 44/00; E21B 21/08

(52) U.S. Cl. CPC E21B 44/00; E21B 21/08; G06F 30/20

(57) ABSTRACT

Some implementations include a method for minimizing a ramp-up time of drilling equipment used to drill a wellbore through a subsurface formation, the method comprising: determining, via an optimization framework, an optimized ramp-up procedure for the drilling equipment with respect to one or more transient dynamics of a drilling fluid; and performing the optimized ramp-up procedure via the drilling equipment.

### FIELD

Some implementations relate generally to drilling a wellbore into the subsurface, more particularly, to the field of flow rate control in automated drilling.

### BACKGROUND

Oil and well drilling processes involve multiple stages, including several instances where pumps need to be stopped and started up to achieve desired flow rates. The time elapsed during these transitions and the drilling fluid characteristics generate transient rheological dynamics that must be addressed to continue production efficiently. The multiple transient dynamics may breach safety requirements, negatively impact wellbore integrity, and slow down drilling. Such transient dynamics may include inadequate control of the equivalent circulating density (ECD), limited adaptability to changing downhole conditions, insufficient consideration of complex rheological properties of drilling fluids, and difficulty in optimizing flow rate trajectories to minimize pressure fluctuations and maintain wellbore pressure within acceptable limits. Conventionally, these transient dynamics are bypassed through inefficient practices like pump start-up, tripping pipe, and pipe rotation. Traditionally, these processes are handled manually by field engineers. The lack of understanding of the underlying physics may lead to energetic destruction, causing sudden peaks in downhole and potentially surface pressure, as well as time loss in production. While some approaches may describe drilling fluid thixotropy and time-dependent rheological characteristics, there remains a lack of investigation of the complete dynamic pressure loss parameters, the resulting peaks in Equivalent Circulating Density (ECD), how to change the flow rate for the optimized and safe performance, etc. Moreover, more traditional approaches may be limited to detailed rheological analyses, which may not always be available in field environments and may be challenging to apply. Compared to manual operations, which typically involve cautious, time-delayed, multi-step ramp-ups, a systematically automated solution may streamline the start-up procedure.

### BRIEF DESCRIPTION OF THE DRAWINGS

Implementation of the disclosure may be better understood by referencing the accompanying drawings.

FIG. 1 depicts an example well system used to drill a well, according to some implementations.

FIG. 2 is a schematic diagram depicting two drilling methodologies and their associated drilling windows, according to some implementations.

FIG. 3 is a flowchart depicting example operations for a pump ramp up cycle, according to some implementations.

FIG. 4 includes two plots depicting various drilling parameters with a pump ramp up time of 2 seconds, according to some implementations.

FIG. 5 includes two plots depicting various drilling parameters with a pump ramp up time of 5 seconds, according to some implementations.

FIG. 6 includes two plots depicting various drilling parameters with a pump ramp up time of 20 seconds, according to some implementations.

FIG. 7 includes two plots depicting various drilling parameters with an optimized pump ramp up time, according to some implementations.

FIG. 8 includes two plots depicting various drilling parameters with a pump ramp up time of 5 seconds and an allowable ECD change, according to some implementations.

FIG. 9 includes two plots depicting various drilling parameters with a pump ramp up time of 20 seconds and an allowable ECD change, according to some implementations.

FIG. 10 includes two plots depicting various drilling parameters with an optimized pump ramp up time and an allowable ECD change, according to some implementations.

FIG. 11 is a block diagram depicting an example computer, according to some implementations.

FIG. 12 is a flowchart depicting a first example method of operations for developing an optimization problem and implementing the optimized solution, according to some implementations.

FIG. 13 is a flowchart depicting a second example method of operations, according to some implementations.

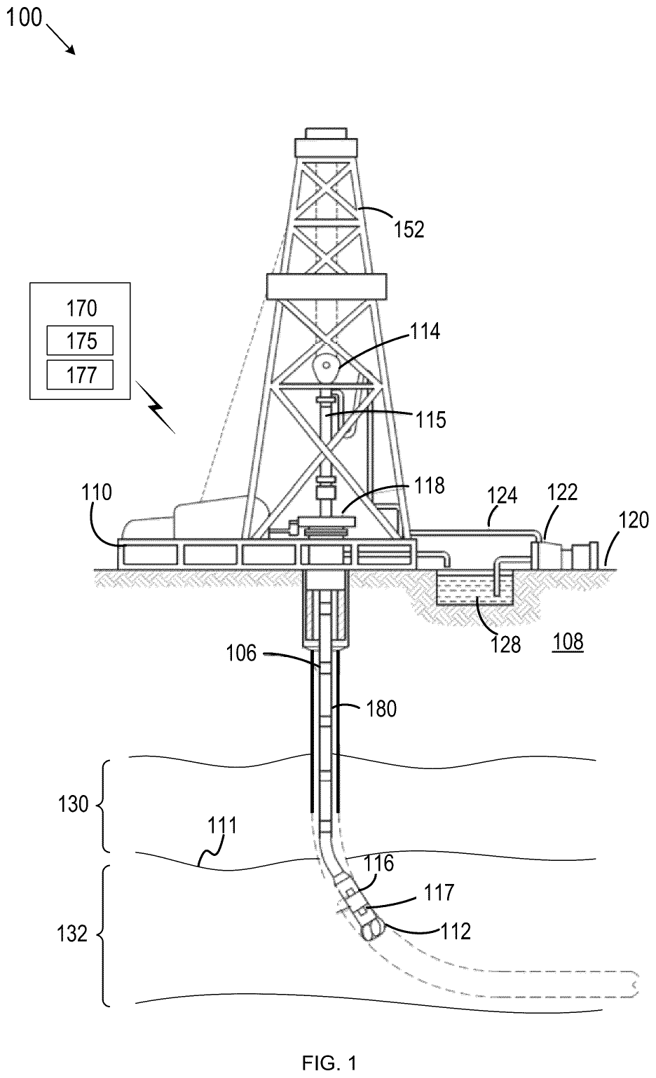

FIGS. 1-13 and the operations described herein are examples meant to aid in understanding example implementations and should not be used to limit the potential implementations or limit the scope of the claims. None of the implementations described herein may be performed exclusively in the human mind nor exclusively using pencil and paper. None of the implementations described herein may be performed without computerized components such as those described herein. Some implementations may perform additional operations, fewer operations, operations in parallel or in a different order, and some operations differently.

### OVERVIEW

To address the challenges with traditional techniques, some implementations may employ transient dynamical models to enable non-linear trajectory optimization (used within the automotive, aerospace, robotics, and other industries) in automated drilling operations. The models may address the wellbore and surface safety requirements while minimizing the waiting time for the most efficient processes, and optimized control of flow rates during drilling may enable safer and more efficient operations. Furthermore, traditional approaches do not provide insight to field engineers on how the trajectory of actuators should be managed, leaving a significant gap in the optimization and control of drilling operations. Addressing these challenges may improve the efficiency, safety, and reliability of drilling processes. By considering the current state of the drilling operation, including factors such as the drilling window, predicted or measured downhole pressure, transient dynamics build-up time, and desired flow rate, an optimization algorithm may then generate safe and time-efficient trajectories for the pumps.

An approach to automated drilling that leverages nonlinear trajectory optimization for enhanced flow rate control during drilling operations is described. Transient dynamics may result in sudden peaks in downhole and surface pressure, potentially leading to energetic destruction and time loss in production due to an inadequate understanding of the physics involved. One approach described herein may employ a transient rheology dynamic model to describe fluid dynamics downhole and generate real-time actuator trajectories based on commonly available on-site measurements. By considering safety and performance constraints, the described approach accounts for various downhole effects, such as hydrostatic pressure effect, momentum effect, gel effect, viscous pressure effect, pressure drop at the bit, and complex rheological properties of drilling fluids. Furthermore, the approach may systematically include additional complexities if available and presented. The approach may determine an optimal flow rate trajectory that minimizes pressure fluctuations and maintains wellbore pressure within the drilling window, ensuring both wellbore and surface safety requirements are met while reducing waiting time for efficient drilling processes.

This description may include example systems, methods, techniques, and program flows that embody aspects of the disclosure. However, this disclosure may be practiced without these specific details. Aspects of this disclosure may also be applied to any other configuration of devices configured to perform drilling optimization. For clarity, some well-known instruction instances, protocols, structures, and techniques have been omitted.

### Example Well System

FIG. 1 depicts an example well system used to drill a well, according to some implementations. The well system 100 includes a drill string 180 having a drill bit 112 disposed in a wellbore 106 for drilling the wellbore 106 in the subsurface formation 108. While depicted for a land-based well system, example implementations may be used in subsea operations that employ floating or sea-based platforms and rigs.

The well system 100 may further include a drilling platform 110 that supports a derrick 152 having a traveling block 114 for raising and lowering the drill string 180. The drill string 180 may include, but is not limited to, drill pipe, drill collars, and drilling assembly 116. The drilling assembly 116 may comprise any of a number of different types of tools including a rotary steerable system (RSS), measurement while drilling (MWD) tools, logging while drilling (LWD) tools, mud motors, etc. A kelly 115 may support the drill string 180 as it may be lowered through a rotary table 118. The drill bit 112 may include roller cone bits, polycrystalline diamond compact (PDC) bits, electro-crushing bits, natural diamond bits, any hole openers, reamers, coring bits, etc. Drilling parameters of drilling the wellbore 106 may be adjusted to increase, decrease, and/or maintain the rate of penetration (ROP) of the drill bit 112 through the subsurface formation 108 and, additionally, steer the drill bit 112 through the subsurface formation 108. The subsurface formation 108 may include multiple formations such as formations 130, 132. The interface between the formations 130 and 132 may be the formation bed boundary 111. The drilling parameters may assist in steering the wellbore 106 to avoid contact and/or penetration of the formation bed boundary 111. Drilling parameters may include weight-on-bit (WOB) and rotations-per-minute (RPM) of the drill string 180. A mud pump 122 (“pump 122”) may circulate drilling fluid through a feed pipe 124 to the kelly 116, downhole through interior of the drill string 180, through orifices in the drill bit 112, back to the surface 120 via an annulus surrounding the drill string 180, and into a retention pit 128. In some implementations, one or more pumps 122 may be used.

In some implementations, various sections of the wellbore 106 such as the vertical, tangent, curve, and horizontal section may require directional drilling to steer the drill bit 112 on a planned well path and/or keep the wellbore 106 in a target formation. Sensors on the drilling assembly 116, such as gamma ray sensors, porosity sensors, resistivity sensors, etc., may log respective measurements while drilling the wellbore 106. The measurement logs may be obtained from the sensors on the drilling assembly 116 and uplinked to the surface 120. In some implementations, the measurements may be communicated to tools on the drilling assembly 116 for processing. The measurements may be processed and utilized to determine the location of the formation bed boundary 111.

In some implementations, a sensor array 117 may collect data within the wellbore 106. The sensor array 117 may include a flow meter and a pressure sensor, although other tools and sensor configurations may be used. The sensor array 117 may be communicatively coupled to a computer 170 at the surface. The data collected by the sensor array 117 may be communicated to the computer 170 in real-time. The computer 170 may include an optimization framework 175 configured to optimize a ramp-up trajectory of the pump 122. The computer 170 also may include a pump controller 177 configured to control operations of the pump 122.

The optimization framework 175 may perform operations to find the minimum of a constrained nonlinear multivariate function. Some implementations may utilize any suitable computerized functionality, approach, and/or combination thereof to find the minimum of the nonlinear multivariate function. For example, some implementations may utilize MATLAB's fmincon function, although any other nonlinear solver, scripting language, and/or computerized functionality may be used. The computerized functionality may be constrained by both linear and non-linear input constraints, making it suitable for problem formulation within an automated drilling environment. By using the computerized functionality to solve the nonlinear trajectory optimization problem for an optimal ramp-up time of the pump 122, an optimized ramp-up procedure that minimizes T-ramp and adheres to the delta ECD max constraint may be obtained, ensuring both safety and efficiency in the drilling process.

In some implementations, other functions may be used by the optimization framework 175. For example, an interior-point optimization approach consists of a default large-scale algorithm based on interior-point methods suitable for a wide range of problems including, but not limited to, large-scale, non-linear, and constrained optimization problems. Some implementations may use Sequential Quadratic Programming (SQP) consisting of a medium-scale algorithm effective for smooth constrained non-linear problems with a smaller number of variables. Some implementations may use an active-set algorithm. The active-set algorithm may be a medium-scale algorithm configured for solving non-linear optimization problems. While effective in determining solutions, it may be less efficient than interior-point or SQP algorithms. Some implementations may use a trust-region-deflective algorithm. The trust-region-deflective algorithm may be a large-scale algorithm designed for problems with continuous first and second derivatives (e.g., gradient and Hessian). This algorithm may be more efficient than other algorithms in solving certain problems, especially when the Hessian is sparse. In some implementations, the optimization framework 175 may use a trust-region-dogleg algorithm for small-scale problems when the problem is unconstrained, has bounds, and/or has constraints. This algorithm may not be ideal for solving optimization problems with general nonlinear constraints.

The constrained nonlinear multivariate function (optimization algorithm) of the optimization framework 175 may utilize one or more simplified Navier-Stokes equations that take into account multiple downhole transient effects such as hydrostatic pressure, the momentum effect, gel effect, viscous pressure effect. The optimization algorithm may also represent the complex rheological behavior of the drilling fluid. The optimization framework 175 may solve for a minimum of Navier-Stokes equations while taking into account the impact of varying shear rate on the gel effect and viscous effect calculations during the optimization procedure. This additional layer of complexity may allow for more accurate modeling of the real-world behavior of drilling fluids and their interaction with the wellbore 106. However, other model besides Navier-Stokes equations may be used to model downhole transient effects within the optimization framework 175.

For example, the optimization framework 175 may use a drift flux model (DFM), a reduced drift flux model (RDFM), a Kaasa model, and any other model, computerized functionality, or approach suitable for modeling transient dynamics in the downhole environment may be used by the optimization framework 175.

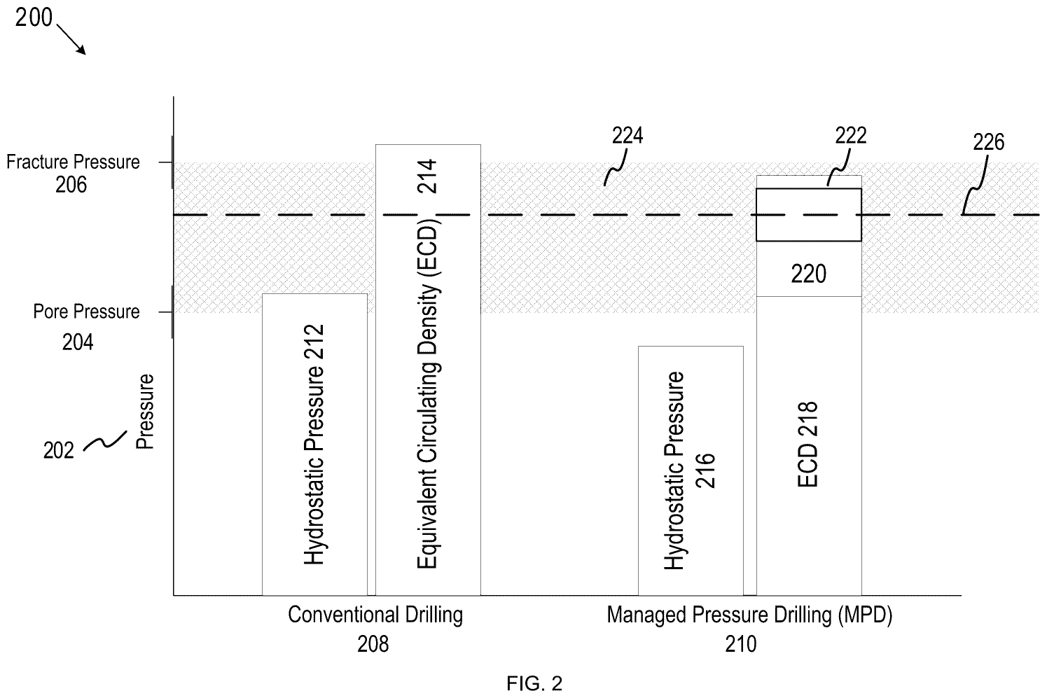

Various cases may demand strict adherence to a target ECD, while others may provide a more lenient drilling window. FIG. 2 is a schematic diagram 200 depicting two drilling methodologies and their associated drilling windows, according to some implementations. The diagram 200 includes an X-axis including the two drilling methodologies: conventional drilling 208 and managed pressure drilling (MPD) 210. The diagram 200 further includes a Y-axis 202 depicting unitless pressure. A drilling window 224 is formed between a pore pressure 204 and a fracture pressure 206. A hydrostatic pressure 212 in convention drilling 208 may be greater than the pore pressure 204. This may be referred to as overbalanced drilling. While this may mitigate wellbore fluids arising to the surface (i.e., kicks), the ECD of drilling fluid may exceed the fracture pressure 206 and lie beyond the drilling window 224. This may jeopardize the integrity of the wellbore, and the ECD 214 may be sub-optimal for drilling when compared to a target ECD 226 within the drilling window 224.

A second methodology depicting managed pressure drilling 210 may include a hydrostatic pressure 216 lower than the pore pressure. This may be referred to as underbalanced drilling. Underbalanced drilling may include advantages such as improved drilling performance and equipment lifespan, but kicks may occur if pressure supply is not constant. An ECD 218 for underbalanced drilling may also be far from the target ECD 226. MPD practices are applied to underbalanced drilling to maintain a bottomhole pressure within a range slightly above the pore pressure 204, which leads to a higher ECD as denoted by the MPD ECD 220. Further process refinement in the form of automated managed pressure drilling may result in a tighter ECD and/or drilling window, as denoted by the Automated MPD ECD 222.

It may be important to maintain an ECD between the pore pressure 204 and fracture pressure 206 to avoid or minimize fluid losses and kick problems. The computer 170 may include functionality that considers the current state of the drilling operation, including factors such as the drilling window, predicted or measured downhole pressure, transient dynamics build-up time, and desired flow rate. The functionality may then generate safe and time-efficient trajectories for the pumps.

Compared to manual operations (which typically involve cautious, time-delayed, multi-step ramp-ups), automated MPD with optimized pump trajectories determined by the computer 170 may eliminate immediate human intervention which may reduce the potential for errors. Optimizing the pump trajectories in automated MPD may also minimize ramp-up times (saving operation costs), increase the safety margin of the entire system by avoiding critical pressure peaks, and ensure the integrity of the wellbore remains operational.

### Example Flowchart of Operations

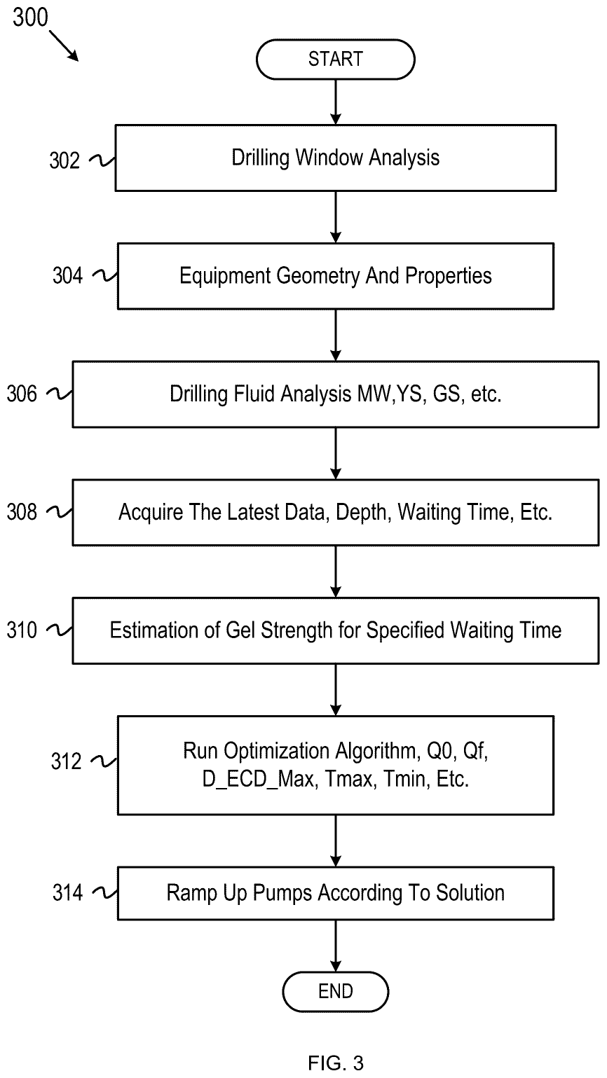

A flowchart of example operations for pump trajectory optimization is now described. FIG. 3 is a flowchart 300 depicting example operations for a pump ramp up cycle, according to some implementations.

At block 302, a drilling window analysis is performed. This may be performed by a user or by the computer 170. For example, the computer 170 may include functionality (hardware and/or software) to determine a drilling window 224 based on a pore pressure 204 and fracture pressure 206 of a wellbore 106. Flow progresses to block 304.

At block 304, equipment geometry and properties of the pump 122 are input as parameters into the optimization framework 175. For example, the equipment geometry and pump specifications may be used as bounds in the optimization problem to be solved by the optimization framework 175. The pore pressure 204 may be a lower bound, and the fracture pressure 206 may be an upper bound. The optimization function may have an objective to minimize the ramp up time of the pump 122. Constraints are set for the optimization function based on known dynamics. For example, the pump 122 may have a maximum rate of change of 100 gallons per minute (gpm) and may be constrained by a maximum flow rate of 1,000 gpm. These may be linear constraints. Other linear constraints may include the pipe diameter of the drilling string 180 and the hole diameter of the wellbore 106. Boundary conditions may also be set within the optimization framework 175. For example, the optimization function of the optimization framework 175 may be bounded by the pump specifications, maximum rate of change, maximum flow rate, etc. Flow progresses to block 306.

At block 306, various parameters of a drilling fluid pumped from the pump 122 through the drill bit 112 are analyzed and input into the optimization framework 175. In some implementations, the optimization framework 175 may analyze a mud weight, a yield strength, a gel strength, hydrostatic pressure of a fluid column, etc. of the drilling fluid in the wellbore 106. In some implementations, the optimization framework 175 may utilize standard mud reports generated by readily available equipment, streamlining the data collection process. Flow progresses to block 308.

At block 308, the latest drilling data, depth of the well, latest waiting time, etc. may be acquired. In some implementations, the latest drilling data may be obtained via the sensor array 117. The drilling data may be input into the optimization framework 175, and the optimization framework 175 may perform various calculations to determine an optimal ramp-up trajectory of the pump 122. Flow progresses to block 310.

At block 310, a gel strength of the drilling fluid may be estimated. While gel strength is known to increase over time, the gel strength may traditionally only measured at intervals of 10 seconds, 10 minutes, and 30 minutes. However, the actual waiting time between drilling operations may differ from these intervals. Therefore, the immediate gel strength may be estimated using lab measurements and the known waiting time. Flow progresses to block 312.

At block 312, the optimization framework 175 may perform the optimization algorithm of the optimization framework 175 with a plurality of defined input parameters (such as information determined at blocks 302-310). For example, the input parameters may include linear constraints such as an initial flow rate (Q0), final flow rate (Qf), etc. The input parameters may also include boundary conditions such as a maximum time to ramp up (Tmax), minimum time to ramp up (Tmin), maximum possible flow rate of the pump 122, etc. Non-linear constraints such as maximum change in ECD (D_ECD_Max) may also be input into the optimization framework as an input parameter. An initial guess may be made for the input parameters, which may be adjusted on prior knowledge and/or experience. Flow progresses to block 314.

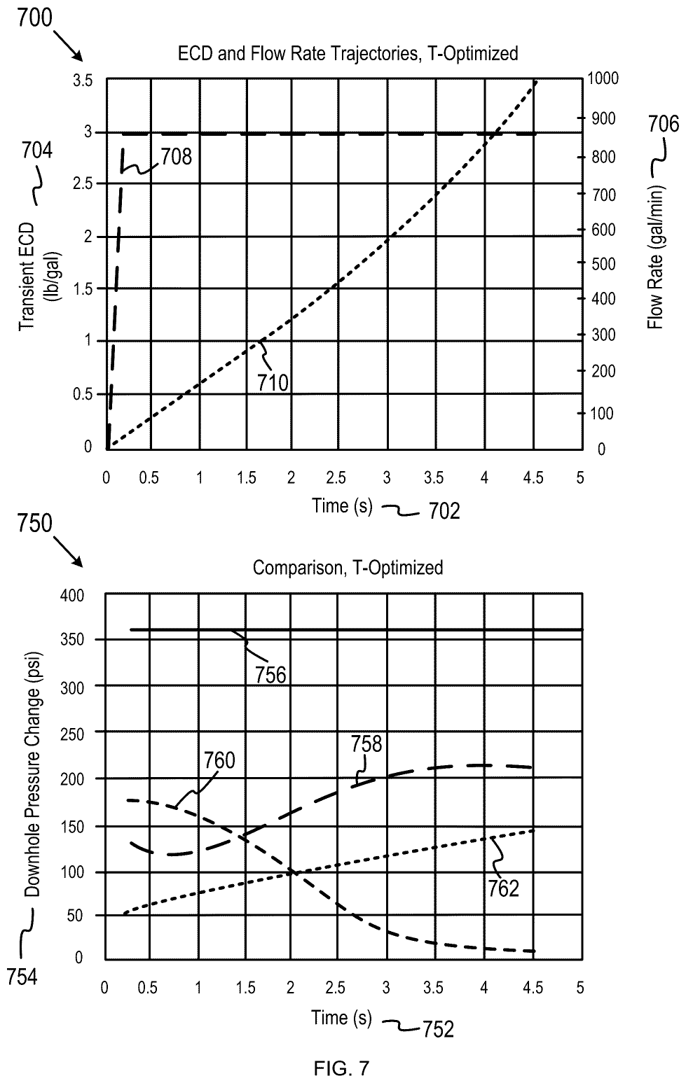

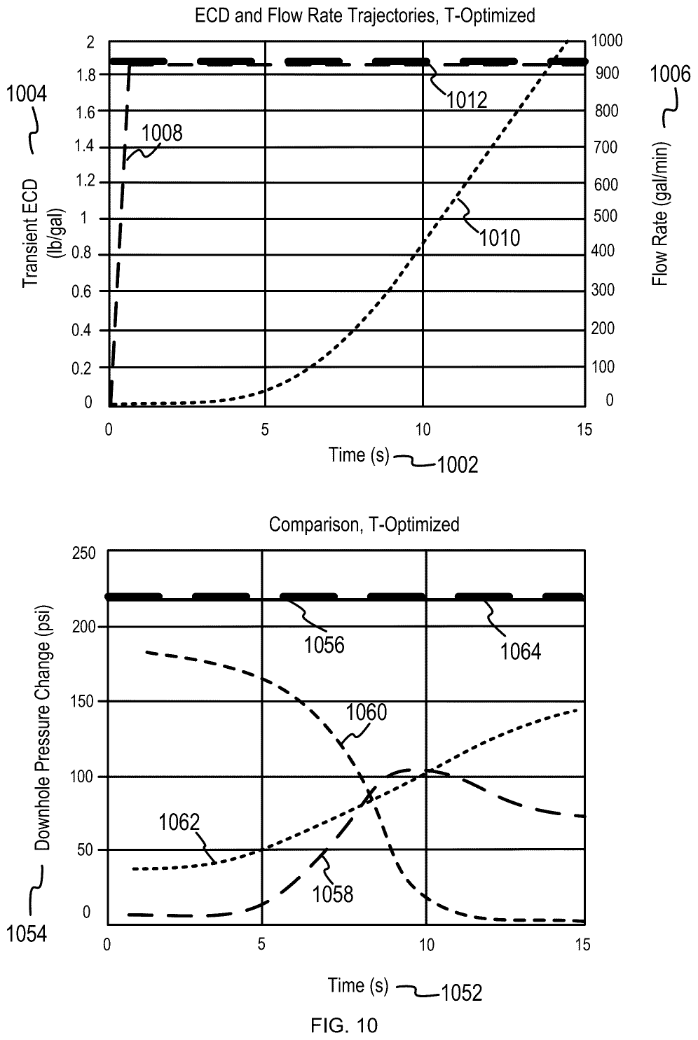

At block 314, the pump 122 is ramped up according to the optimal solution to the nonlinear optimization problem. For example, the pump controller 177 may be configured to actuate the pump 122 to achieve a flow rate trajectory that minimizes T-ramp while satisfying the input parameters. Such optimizations are shown in the simulated optimizations of FIGS. 7 and 10. In some implementations, the optimization framework 175 may guide the ramp-up process for the pump 122 from a zero flow rate until a desired flow rate is reached for drilling. Flow of the flowchart 300 ceases.

The approach shown in FIG. 3 may enable safer and more efficient drilling operations, reducing risks of wellbore instability, lost circulation, and formation damage, enhanced wellbore pressure control, reduced non-productive time, potential for cost savings through optimized drilling fluid usage and reduced wellbore problems, etc. The operations of the flowchart 300 may have applicability across a range of drilling scenarios and wellbore configurations.

### Example Simulations

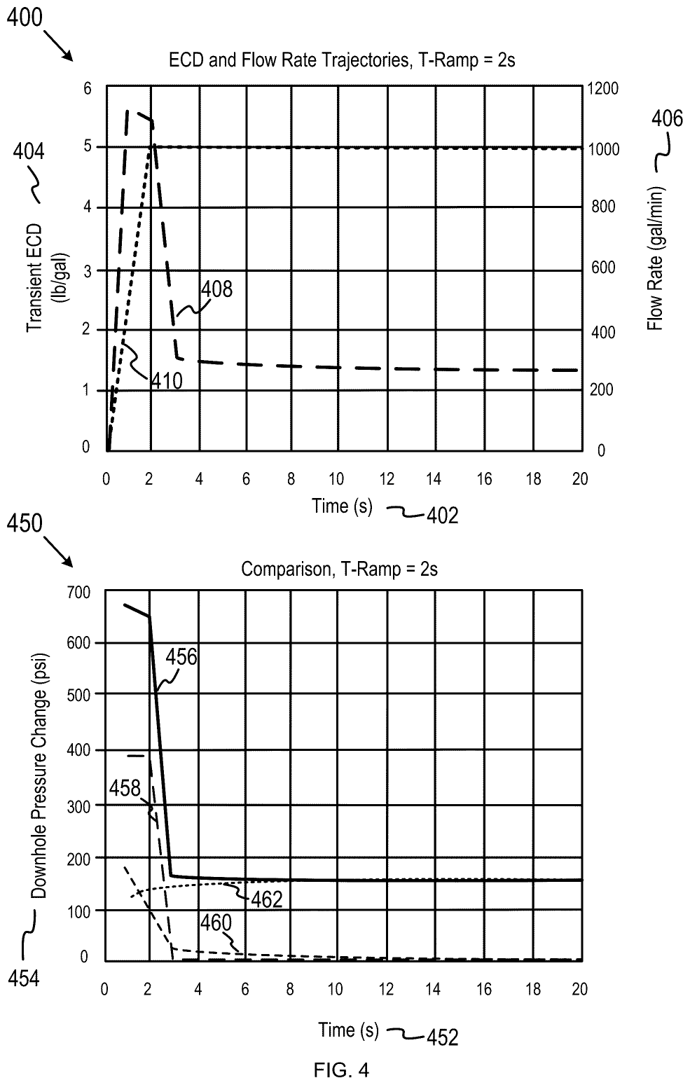

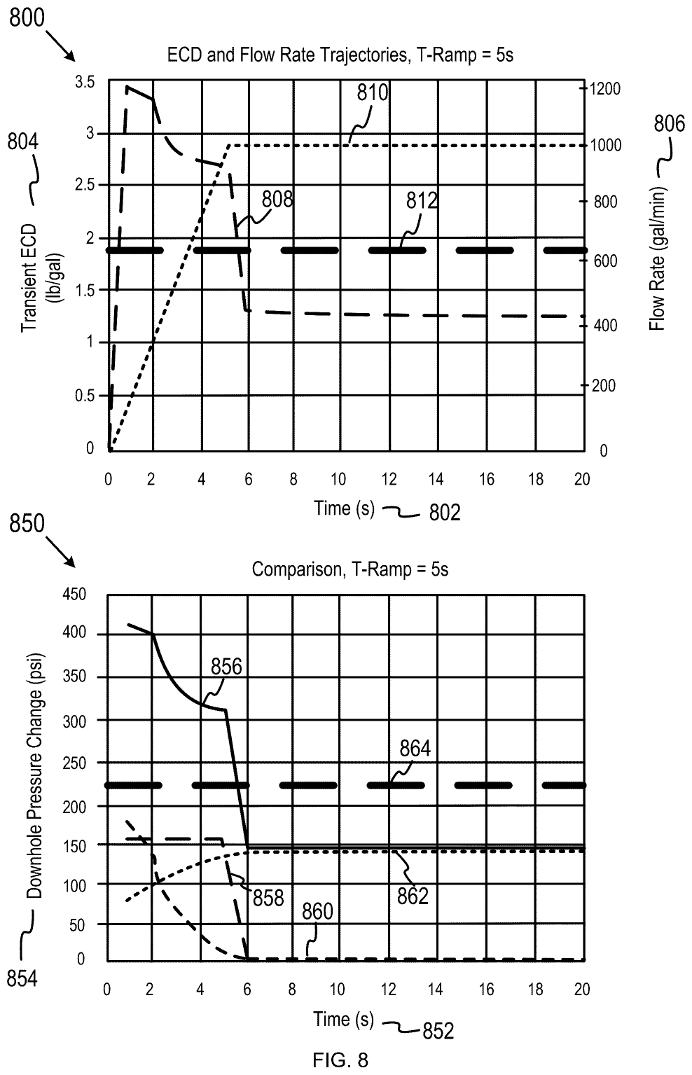

Drilling operations may be simulated to show the effects of flow rate, rheological properties, and other downhole phenomena on resulting ECDs and drilling windows. In simulated results, differences may be observed between ramp up cycles having a constant flow rate case increase and pump ramp ups that utilize nonlinear optimization. In Case 1, the objective is to ramp up as fast as possible with a relatively loose ECD window. In Case 2, a very tight drilling window is present, making the ramp-up process more challenging. In both cases, a nonlinear optimization approach achieves a faster ramp-up time. Examples of these simulations are depicted in FIGS. 4-10; simulations relating to Case 1 are depicted in FIGS. 4-7, while simulations related to Case 2 are depicted in FIGS. 8-10. Optimized pump trajectories output from the optimization framework 175 are shown in FIGS. 7 and 10 for both Case 1 and Case 2.

FIG. 4 includes two plots depicting various drilling parameters with a pump ramp up time of 2 seconds, according to some implementations. A plot 400 includes an X-axis 402 of time in seconds, a first Y-axis 404 of a transient ECD in pounds per gallon (lb/gal, or ppg), a second Y-axis 406 of drilling fluid flow rate in gpm. An ECD change 408 describes the rate of variation or change of the equivalent circulating density during the pump ramp-up process with respect to time. A flow rate trend 410 shows a linear ramp up to 1,000 gpm in 2 seconds. In the plot 400, the pump 122 are ramped up within two seconds, leading to a spike in the transient ECD above 5.5 ppg within a short time interval.

A plot 450 shows comparisons between various phenomena of the drilling fluid during the 2 second pump ramp up. Plot 450 includes an X-axis 452 of time in seconds and a Y-axis of downhole pressure change in pounds per square inch (psi). A total pressure peak 456 falls rapidly after the two second ramp-up period of the pump 122. Also included in the plot 450 are three phenomena of the drilling fluid that affect the pump ramp up, the total pressure peak 456, and whether a ramp up cycle remains within the limits of safe operation. For example, the plot 450 includes a momentum effect 458, a gel effect 460, and a viscous effect 462. The momentum effect 458 may refer to pressure changes that are directly proportional to the acceleration and deceleration of drilling fluid via the pump 122. The gel effect 460 may refer to the drilling fluid's tendency to coagulate and form gel microstructures when not flowing. Longer wait times between running the pump 122 may contribute to a higher gel strength of the drilling fluid. This may make the initial pump ramp up more difficult and result in a higher undesirable downhole pressure peak. The gel effect 460 may be more dominant in early times but largely vanishes after 3 seconds in plot 450. The third phenomenon is the viscous effect 462. The viscous effect 462 refers to frictional forces between the drilling fluid and an internal surface of the drilling string 180. In some implementations, the frictional forces may also be present between an exterior of the drilling string 180 and walls of the wellbore 106. The viscous effect 462 may be dependent on mud and/or drilling fluid type, the type of pipe used, cutting concentration in the wellbore 106, etc. Overcoming the viscous effect 462 requires additional output from the pump 122. However, this may also increase the downhole pressure. The downhole pressure peak 456 may depict the cumulative effects (i.e., the sum) of the pressure contributions from the gel effect 460, momentum effect 458, and viscous effect 462. For example, a massive drop in the momentum effect 458 after the two-second pump ramp-up coincides with a massive drop in the downhole pressure peak 456 after two seconds. This is because the drilling fluid is accelerated during ramp-up, but a linear flow rate is maintained after two seconds. As stated above, the strength of the momentum effect may have a direct relationship with the acceleration of the drilling fluid. The gel effect 460 similarly fades after this time period because of gel breakdown in the flowing drilling fluid, and the viscous effect 462 is the primary downhole pressure driver after three seconds.

The combination of the momentum effect 458, gel effect 460, and viscous effect 462 may push the downhole pressure peak 456 outside of a tolerable range. In some implementations, the spike in the ECD change 408 of plot 400 may exceed the fracture pressure of the wellbore, leading to potential drilling fluid losses. An allowable or a target ECD change may be approximately 2-3 ppg, and the short ramp up time of FIG. 4 may exceed the allowable ECD change by not considering the momentum effect 458, gel effect 460, viscous effect 462, hydrostatic pressure, other dynamics, etc.

Drilling fluid losses may contribute to a decreased hydrostatic pressure within the wellbore 106 during drilling. A reduced hydrostatic pressure may create a situation where the wellbore pressure is less than the pore pressure of the formation, thereby introducing the risk of a kick. A kick is an unintended influx of formation fluids into the wellbore 106. If not controlled promptly, a kick may escalate to a blowout, which is a violent and uncontrolled release of formation fluids. This is a critical safety concern. Therefore, initial fluid losses, while seemingly minor, may set off a chain of events that may compromise the safety and integrity of the entire drilling operation.

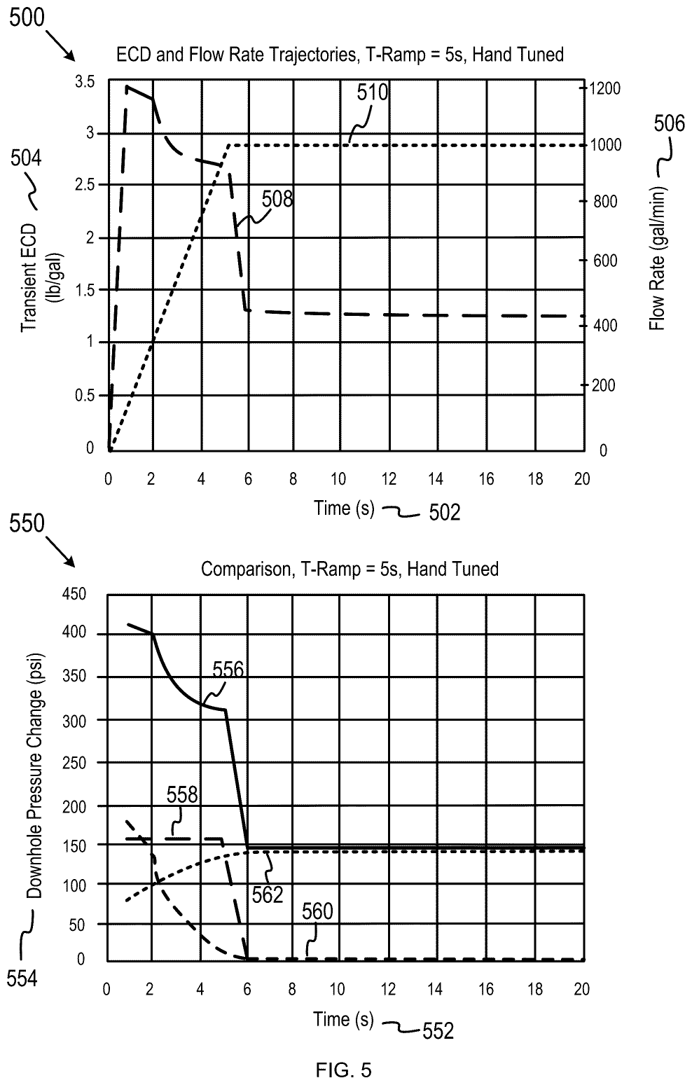

FIG. 5 includes two plots depicting various drilling parameters with a pump ramp up time of 5 seconds, according to some implementations. The plots 500, 550 may be adjusted by an operator or field engineer at the surface (i.e., hand tuned). The plot 500 includes an X-axis 502 of time in seconds, a first Y-axis 504 of a transient ECD in ppg, and a second Y-axis 406 of drilling fluid flow rate in gpm. Plot 550 includes an X-axis 552 of time in seconds, a Y-axis 554 of downhole pressure change in psi, a total pressure peak 556, a momentum effect 558, a gel effect 560, and a viscous effect 562.

An ECD change 508 spikes within the first two seconds because of the gel effect 560. The gel effect 560 is dominant in early time but largely subsides because of gel breakdown after six seconds. However, additional contributions to the downhole pressure change from the momentum effect 558 and viscous effects 562 in early time may exceed an allowable ECD change. The flow rate 510 may ramped within five seconds via hand-tuning by a crew or operator at the surface. The viscous effect 562 effectively contributes the entirety of the downhole pressure peak 556 after six seconds, because the gel structure has completely broken down at this point. The momentum effect 558 initially contributes a substantial portion of the downhole pressure peak 556 in the five second ramp-up period (greater than 150 psi per second) but tapers off after the ramp-up period concludes. As shown, the gel effect 560 and momentum effect 558 are dominant in the first two seconds, the gel breaks down rapidly within the two to five second mark, and the viscous effect 562 drives the downhole pressure peak 556 thereafter.

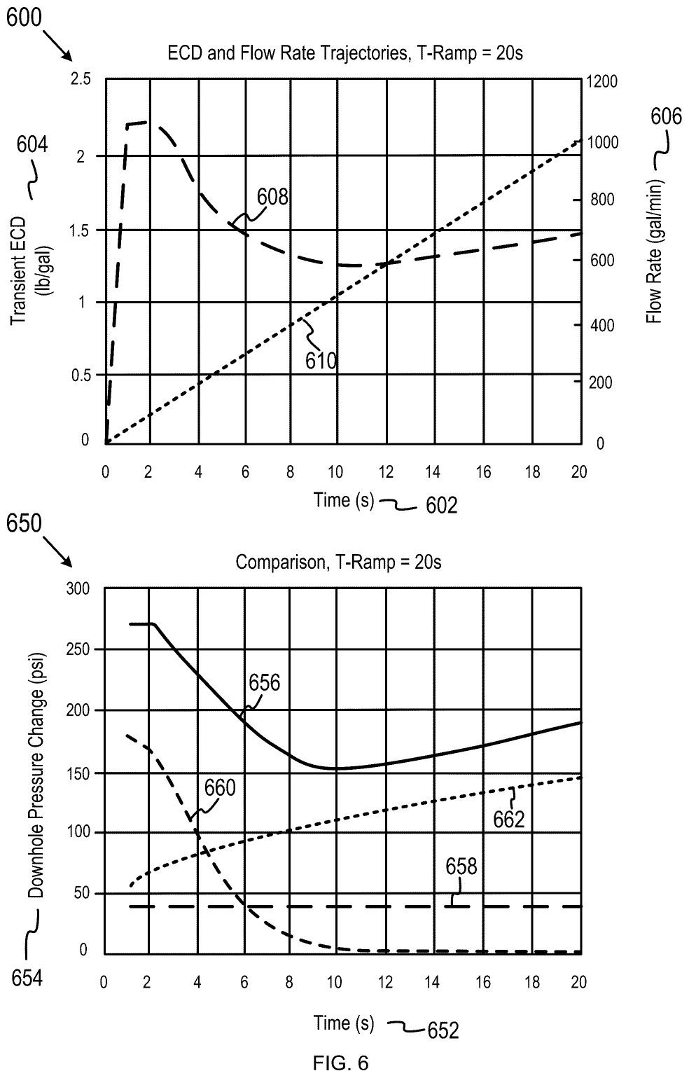

FIG. 6 includes two plots depicting various drilling parameters with a pump ramp up time of 20 seconds, according to some implementations. The plot 600 includes an X-axis 602 of time in seconds, a first Y-axis 604 of a transient ECD in ppg, a second Y-axis 606 of drilling fluid flow rate in gpm, an ECD change 608, and a flow rate 610. Plot 650 includes an X-axis 652 of time in seconds, a Y-axis 654 of downhole pressure change in psi, a total pressure peak 656, a momentum effect 658, a gel effect 660, and a viscous effect 662. The ECD change 608 peaks between 2 and 2.5 seconds due to the longer ramp-up period with a linear flow rate increase. The momentum effect 658 is largely static, contributing approximately ˜40 psi of an increase to the downhole pressure change over time. The viscous effect 662 becomes the dominant pressure driver around four seconds because of frictional forces within the drill string 180.

In FIG. 6, a pump ramp-up time (T-ramp) of 20 seconds is selected to show that slow ramp up procedures may still breach the requirements of safe operation. For example, the linear ramp up of the flow rate 610 still exceeds safety concerns by not factoring in the gel effect 660 in early times. The gel effect 660 is the dominant force affecting drilling fluid rheology in the early stages of pump ramp-up, even with the longer ramp up period. Similar to FIGS. 4 and 5, the gel effect 660 substantially breaks down in the first six seconds because of the moving drilling fluid. The gel effect 660 has a large effect on early-time pump ramp ups, and the optimization framework 175 must account for the gel effect 660 when determining an optimal pump trajectory.

FIG. 7 includes two plots depicting various drilling parameters with an optimized pump ramp up time, according to some implementations. The plot 700 includes an X-axis 702 of time in seconds, a first Y-axis 704 of a transient ECD in ppg, a second Y-axis 706 of drilling fluid flow rate in gpm, an ECD change 708, and a flow rate 710. Plot 750 includes an X-axis 752 of time in seconds, a Y-axis 754 of downhole pressure change in psi, a total pressure peak 756, a momentum effect 758, a gel effect 760, and a viscous effect 762.

In plot 700, the optimization framework 175 may be configured to ramp up the pump 122 according to the objective of the optimization function (minimizing T-ramp) within given bounds and constraints. For example, the optimization framework 175 may iteratively search for the optimal solution that minimizes the objective function while satisfying the constraints, such as the delta ECD max constraint, which may be shaped by the momentum effect 758, gel effect 760, viscous effect 762, etc. In contrast to plots 400, 500, and 600 which may have been manually adjusted, the ECD change and flow rate of plot 700 are optimized via the optimization framework 175. Rather than peaking subsequently declining, the optimization framework increases the rate of change of the ECD linearly within 0.5 seconds and maintains an ECD change increase of 3 ppg thereafter without exceeding it. The allowable ECD change and/or a maximum ECD change may be input into the optimization framework 175.

To avoid an ECD change limit violation while ramping the pump 122 in a short timeframe, the optimization framework 175 maintains a linear flow rate increase until approximately two to three seconds. After three seconds, the rate of change increases. In some implementations, the flow rate may increase quadratically as the optimization framework 175 increments upward. The ramp-up may begin with a lower flow rate that is then incremented flow rate accelerations via the optimization algorithm. While linear ramp up of FIG. 6 takes 20 seconds, safety concerns are still exceeded by not factoring in gel effect. The non-linear solution output by the optimization framework 175 in FIG. 7 takes 25% of the time (less than 5 seconds) to ramp-up the pump 122 and introduces additional safety measures to keep the ECD change within an acceptable limit.

During the ramp-up process, the downhole pressure peak 756 remains constant. The optimization framework 175 achieves the constant downhole pressure peak 756 and corresponding ECD change by adjusting the flow rate with respect to the various subsurface phenomena. For example, the optimization framework 175 is aware that the gel effect 760 is the dominant phenomena in early-time pump ramp up and fades quickly thereafter, as seen in FIGS. 4-6. The optimization framework 175 may accelerate the flow rate 710 after 2-3 seconds coinciding with a near elimination of the gel effect 760 around the same time. While waiting for the gel effect 760 to subside, the optimization framework 175 considers the increasing momentum effect 758 and viscous effect 762 to maintain the constant downhole pressure peak 756. The reduction in the gel effect 760 is coincided by an increase in the momentum effect 758 because of flow rate acceleration. Similar to FIGS. 4-6, the viscous effect 762 increases with time. The acceleration of the flow rate 710 from a linear increase to a steeper, non-linear increase induces a pressure change denoted by the momentum effect 758, which remains the dominant force driving the downhole pressure peak 756.

When compared to FIGS. 4-6, the optimization framework 175 is able to achieve the fastest ramp-up time without violating constraints of the computerized functionality of the optimization framework 175 (and the constraints of the wellbore 106). While both of the quicker non-optimized ramp-up times (FIGS. 4-5) and the slower ramp-up time (FIG. 6) resulted in ECD change spikes, the optimized pump trajectory output from the optimization framework 175 in plot 700 reaches a target ECD rate of change in ˜0.25 seconds via a non-linear solution. The ECD changes are maintained via flow rate changes to offset various subsurface dynamics. The non-linear solution (optimized ramp-up) takes 25% of the time (less than 5 seconds) of a conservative flow rate, such as the 20 second ramp-up in plot 600 and introduces additional safety in keeping the ECD change within an acceptable limit.

FIGS. 8-10 describe simulations with respect to Case 2, these simulations having a tight drilling window. FIG. 8 includes two plots depicting various drilling parameters with a pump ramp up time of 5 seconds and an allowable ECD change, according to some implementations. A plot 800 includes an X-axis 802 of time in seconds, a first Y-axis 804 of a transient ECD in ppg, a second Y-axis 806 of drilling fluid flow rate in gpm, an ECD change 808, and a flow rate 810. Plot 850 includes an X-axis 852 of time in seconds, a Y-axis 854 of downhole pressure change in psi, a total pressure peak 856, a momentum effect 858, a gel effect 860, and a viscous effect 862. The plot 800 further includes an allowable ECD change 812. As seen by the ECD 808 change, the ECD change 808 during ramp-up far exceeds the allowable ECD change 812. The plot 850 also includes a Delta ECD Max Constraint 864 corresponding to the allowable ECD change 812.

The plots 800, 850 may appear similar to the plots 500, 550. For example, the gel effect 860 mimics a similar drop to the gel effect 560 due to gel breakdown after two seconds, and the viscous effect 862 contributes the bulk of the downhole pressure peak 856 after six seconds. The Delta ECD Max Constraint 864 denotes the maximum transient pressure limit corresponding to the allowable ECD change 812. The gel effect 860 and momentum effect 858 dominate the downhole pressure peak 856 in early time (<2 seconds). A steep drop in the downhole pressure peak 856 coincides with gel breakdown between two and five seconds, and a decline in the momentum effect 858 coincides with the deceleration of the flow rate 810 at the end of the pump ramp-up cycle (five seconds). As shown, the downhole pressure peak 856 exceeds the Delta ECD Max Constraint 864 for the entirety of the pump ramp-up cycle. This is not ideal for safe drilling operations.

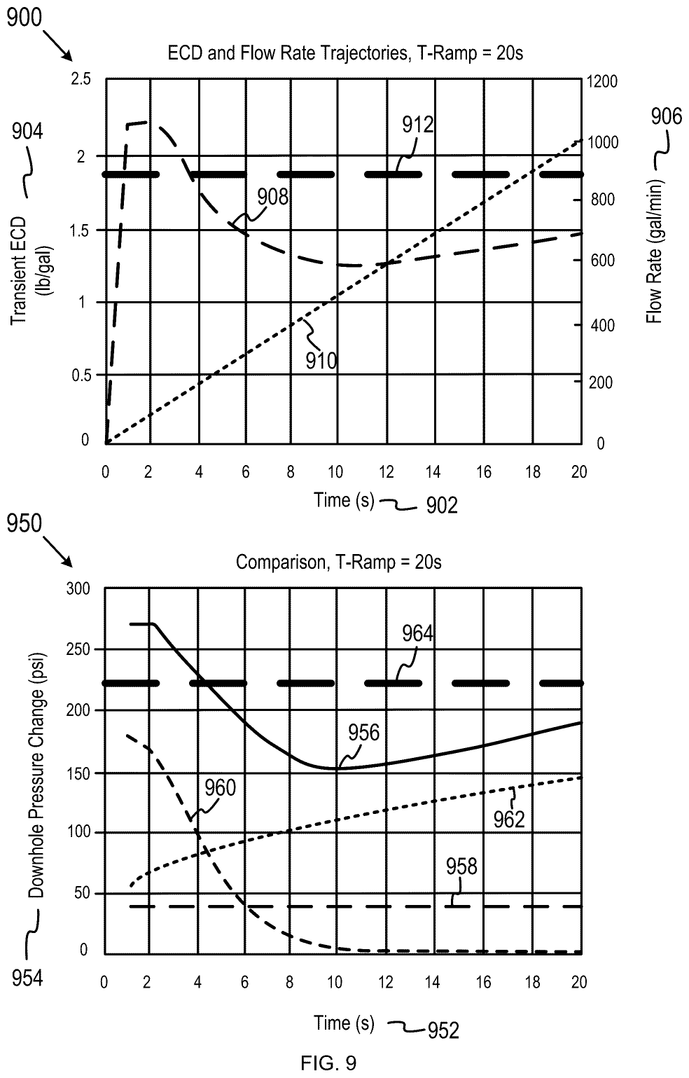

FIG. 9 includes two plots depicting various drilling parameters with a pump ramp up time of 20 seconds and an allowable ECD change, according to some implementations. A plot 900 includes an X-axis 902 of time in seconds, a first Y-axis 904 of a transient ECD in ppg, a second Y-axis 906 of drilling fluid flow rate in gpm, an ECD change 908, and a flow rate 910. Plot 950 includes an X-axis 952 of time in seconds, a Y-axis 954 of downhole pressure change in psi, a total pressure peak 956, a momentum effect 958, a gel effect 960, and a viscous effect 962. Similar to the plots 800, 850, plots 900 and 950 include an allowable ECD change 912 and a Delta ECD Max Constraint 964, respectively. As shown, the ECD change 908 exceeds the allowable ECD change 912 despite the longer ramp-up period.

In the plot 850, the Delta ECD Max Constraint 964 is largely identical to the Delta ECD Max Constraint 964 of FIG. 8. The maximum transient pressure limit is not to exceed approximately 225 psi/second. The longer ramp up time of twenty seconds, as seen in FIG. 9, still manages to exceed the Delta ECD Max Constraint 964. The linear increase to the flow rate 910 over twenty seconds renders the momentum effect 958 as a small and unchanging contribution to the downhole pressure peak 965 during pump ramp-up. The viscous effect 962 contributes similarly to the downhole pressure peak 956 as the viscous effects 562, 662, 762, and 862. Depending on the pump ramp-up time, the viscous effect causes a ˜400-80 psi increase of the downhole pressure peak 956 at the beginning of the ramp-up period and concludes with a 150 psi/s contribution at the end of the ramp-up period. The viscous effect 962 generally follows this trend and dominates the downhole pressure response after approximately four seconds. Prior to four seconds in the ramp-up cycle, however, the downhole pressure peak 956 exceeds the Delta ECD Max Constraint 964. This is because the longer ramp-up time of the pump 122 has not factored in the gel effect 960, which dominates the downhole pressure peak 956 in early time.

FIG. 10 includes two plots depicting various drilling parameters with an optimized pump ramp up time and a maximum ECD, according to some implementations. A plot 1000 includes an X-axis 1002 of time in seconds, a first Y-axis 1004 of a transient ECD in ppg, a second Y-axis 1006 of drilling fluid flow rate in gpm, an ECD 1008, and a flow rate 1010. Plot 1050 includes an X-axis 1052 of time in seconds, a Y-axis 1054 of downhole pressure change in psi, a total pressure peak 1056, a momentum effect 1058, a gel effect 1060, and a viscous effect 1062. Similar to FIG. 7, the flow rate 1010 optimized by the optimization framework 175 increases non-linearly and linearly. The optimization framework 175 increases the flow rate 1010 nonlinearly until approximately 8 seconds and maintains a linear increase to the flow rate 1010 thereafter. This optimized flow rate trajectory enables the ECD 1008 to reach the allowable ECD change 1012 without exceeding it.

The plot 1050 further includes a Delta ECD Max Constraint 1064 corresponding to the allowable ECD change 912. In plot 1050, the downhole pressure peak 1056 does not exceed the delta ECD max constraint 1064. The main challenge of Case 2 (FIGS. 8-10) is that the gel strength, contributing to the gel effects 860-1060, contributes substantially to the downhole pressure peaks 856-1056. The downhole pressure peaks 856 and 956 exceed the delta ECD max constraints 864 and 964, respectively, during their pump ramp-up cycles. With a linear ramp-up, such as the linear flow rate increase of the flow rate 910 in FIG. 9, the momentum and viscous effects 958, 962 push the downhole pressure peak 956 over the constraint, even when the ramp-up time is selected to be sufficiently long, such as 20 seconds. This results in a violation of the constraint and potential issues during the drilling process.

On the other hand, the nonlinear optimization method utilized by the optimization framework 175 (in FIGS. 7 and 10) is aware that increasing acceleration or flow rate before the gel is broken will result in violating the delta max ECD constraint. Therefore, the optimization framework 175 generates a nonlinear trajectory that focuses on breaking the exponentially decaying gel effect 1060 first, followed by rapidly increasing the acceleration of the flow 1010 rate to optimize the ramp-up time while respecting the constraints. This is seen by the flow rate 1010, for example.

Thus, the optimization framework's nonlinear optimization not only respects the constraints, unlike the linear ramp-up cases at 2, 5, and 20 seconds (FIGS. 4-6 and 8-9), but it also achieves a shorter ramp-up time. For example, the ramp up time achieved in plot 1000 is slightly less than 15 seconds, given the tight drilling window. This demonstrates the effectiveness of nonlinear optimization in addressing the challenges posed by tight drilling windows, ensuring both safety and efficiency in the drilling process.

The computerized functionality of the optimization framework 175 may analyze and be aware of drilling dynamics attributable to the momentum effect 1058, gel effect 1060, and viscous effect 1062, hydrostatic pressure, etc. and their impact on the downhole pressure peak 1056 to ensure drilling operations remain within safe margins. The downhole pressure peak 1056 is maintained just below the Delta ECD Max Constraint 1064 by adjusting the flow rate 1010 with reference to the transient dynamics of plot 1050. For example, the gel effect 1060 begins to decline substantially after five seconds, and around this time is when the optimization framework 175 accelerates the flow rate 1010. The flow rate acceleration increases the momentum effect 1058, offsetting the decline in the gel effect 1060. However, the increase in the flow rate 1010 change is performed with additional reference to the increasing viscous effect 1062. By modulating the flow rate 1010 between the momentum effect 1058, gel effect 1060, viscous effect 1062, and other transient effects, the optimization framework 175 is able to ramp up the pumps with a nonlinear solution while maintaining a constant downhole pressure peak 1056 that does not exceed the Delta ECD Max Constraint 1064.

In other prior examples, the optimization framework 175 may ensure drilling operations remain in safe operating parameters while providing a faster ramp-up time. For example, in Case 1, if the manual-linear ramp-up time is selected as 20 s (FIG. 6), it does not violate the constraints, whereas in Case 2 (FIG. 9), the linear ramp-up does violate the Delta ECD Max constraint due to the tight drilling window. This demonstrates that the nonlinear optimization approach not only provides a faster ramp-up but also ensures safer operations while being adaptable to various drilling windows, fluid properties, wellbore geometries, etc.

The linear ramp-up of FIGS. 6, 9 result in an increased pressure peak or, for the same pressure peak, an increased total elapsed time. This is because the linear ramp-up does not efficiently break the gel, trading off between the momentum effect and the viscous effect.

The nonlinear optimization of FIGS. 7-10 output by the optimization framework 175 does not exhibit an instantaneous peak. Instead, the resulting pressure peak reaches the upper limit of the drilling window, the fracture pressure 206, and the optimization framework 175 adjusts the flow rate increase nonlinearly throughout the entire ramp-up procedure. This maximizes the time spent at the maximum allowable pressure point, reducing the time required for the initial flow rate to reach the final flow rate. The nonlinear optimization seen in FIGS. 7, 10 may also eliminate fluctuations and result in more stable, safer ramp-up operations, enhancing the efficiency and reliability of the drilling process.

In Case 2 (FIGS. 7-10), the primary challenge is managing the gel strength within a tight drilling window. In FIGS. 7-10, the gel strength is very close to the delta ECD max constraint. With a linear ramp-up as seen in FIGS. 6 and 9, the momentum and viscous effects push the pressure peak over the constraint, even when the ramp-up time is selected to be sufficiently long, such as 20 seconds. This results in a violation of the constraint and potential issues during the drilling process. The linear ramp-up approach seen in FIGS. 4-6 and 8-9 also requires specific knowledge and adaptability, as the same ramp-up slope may not be applicable to every field, fluid property, or system geometry such as pipe diameter and hole diameter. On the other hand, the nonlinear optimization of the optimization framework 175 aims to be more robust and adaptable to a variety of drilling environments.

To maintain a safe ECD change and to combat the gel effect, the optimization algorithm is aware that increasing acceleration or flow rate before the gel is broken will result in violating the constraint. Therefore, the optimization framework 175 generates a nonlinear trajectory that focuses on breaking the exponentially decaying gel effect first and then rapidly increases the acceleration and flow rate to optimize the ramp-up time while respecting the constraints. This is seen in both FIGS. 7 and 10, where part of the ramp-up is non-linear, and part of the ramp-up is linear. As a result, the nonlinear optimization not only respects given constraints (unlike the linear ramp-up cases of FIGS. 4-6 and 8-9), but it also achieves a shorter ramp-up time. In FIG. 10, the ramp-up is slightly less than 15 seconds. This demonstrates the effectiveness of the nonlinear optimization approach in addressing the challenges posed by tight drilling windows, ensuring both safety and efficiency in the drilling process.

### Example Computer

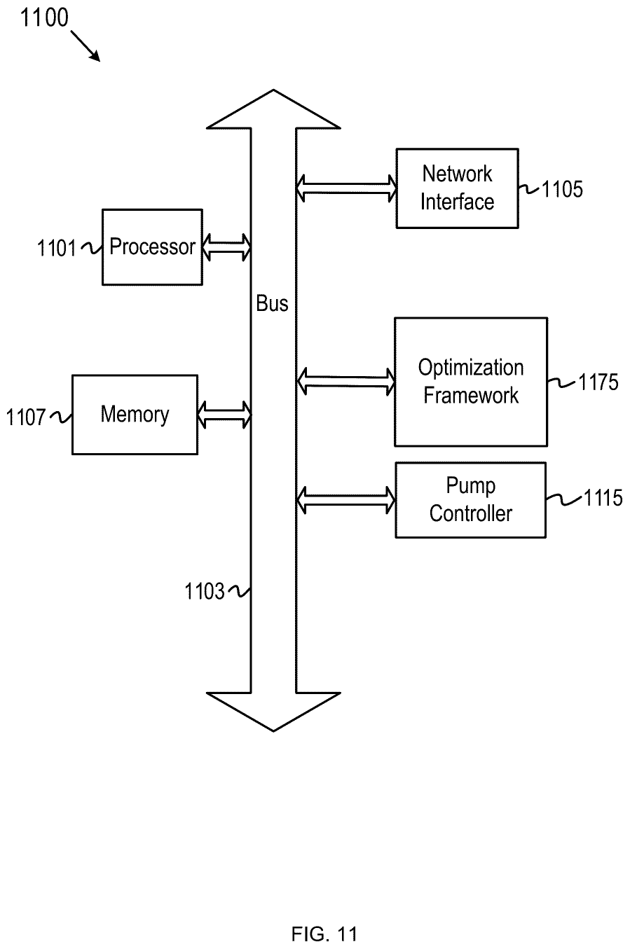

FIG. 11 is a block diagram depicting an example computer 1100, according to some implementations. The computer 1100 includes a processor 1101 (possibly including multiple processors, multiple cores, multiple nodes, and/or implementing multi-threading, etc.). The computer 1100 includes memory 1107. The memory 1107 may be system memory or any one or more of the above already described possible realizations of machine-readable media. The computer 1100 also includes a bus 1103 and a network interface 1105. The computer 1100 may communicate via transmissions to and/or from remote devices via the network interface 1105 in accordance with a network protocol corresponding to the type of network interface, whether wired or wireless and depending upon the carrying medium. In addition, a communication or transmission may involve other layers of a communication protocol and or communication protocol suites (e.g., transmission control protocol, Internet Protocol, user datagram protocol, virtual private network protocols, etc.).

The computer 1100 may include an optimization framework 1175 and a pump controller 1115 which may perform the operations described herein. For example, optimization framework 1175 may be configured to perform the above-described operations with reference to the optimization framework 175 of FIG. 1. In some implementations, the computer 1100 may be similar to FIG. 1's computer 170. The optimization framework 1175 integrates an understanding of fluid dynamics, particularly from a transient rheology dynamic model, to generate optimal actuator trajectories for drilling processes. The pump controller 1115 may be configured to implement an optimized ramp-up trajectory output by the optimization framework 1175 to the pump 122 and correlated equipment. In some implementations, the pump controller 1115 may automate the use of actuators to address the transient dynamics downhole. The pump controller 1115 generates a trajectory for automating the actuator control based on the trajectory output from the optimization framework 1175, ensuring a smooth transition between drilling phases. For example, the pump controller 1115 may be an equipment actuation system configured to alter the flow rate of drilling fluid to achieve the optimal ramp-up trajectory. In some implementations, the optimization framework 1175 and the pump controller 1115 may be in communication. Any one of the previously described functionalities may be partially (or entirely) implemented in hardware and/or on the processor 1101. For example, the functionality may be implemented with an application specific integrated circuit, in logic implemented in the processor 1101, in a co-processor on a peripheral device or card, etc. Further, realizations may include fewer or additional components not illustrated in FIG. 11 (e.g., video cards, audio cards, additional network interfaces, peripheral devices, etc.). The processor 1101 and the network interface 1105 are coupled to the bus 1103. Although illustrated as being coupled to the bus 1103, the memory 1107 may be coupled to the processor 1101.

### Example Optimization Flow

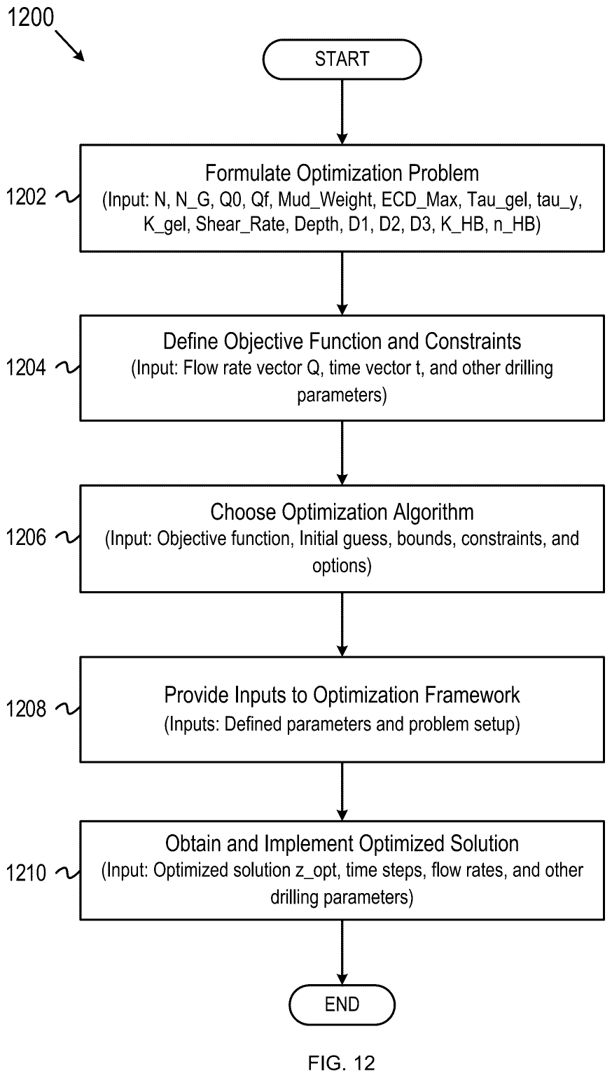

FIG. 12 is a flowchart 1200 depicting a first example method of operations for developing an optimization problem and implementing the optimized solution, according to some implementations. Operations of the flowchart 1200 may be described with reference to FIGS. 1-11. The operations of the flowchart 1200 may be performed by any combination of hardware/software, etc. Operations of the flowchart 1200 begin at block 1202.

At block 1202, a user and/or the computer 170 may formulate an optimization problem. For example, a user and/or in combination with the computer 170 may determine drilling parameters such as the number of time steps to be optimized (N), and a number of initial guess time steps (N_G). Initially, it may not be known how long a pump ramp up procedure may take. Other parameters to be determined for the optimization problem may include an initial flow rate in gpm (Q0), a final desired flow rate in gpm (Qf), the mud weight in ppg (mud_weight), the maximum allowed ECD in ppg (ECD_Max), a gel strength of the drilling fluid in lbf/100 ft² (Tau_gel), the yield stress of the drilling fluid in lbf/100 ft² (Tau_y), a dimensionless gel constant (K_gel), the shear rate of the drilling fluid in 1/s (Shear_Rate), the depth of the well in feet (Depth), the hole diameter in inches (D1), the outer diameter of the drilling string 180 in inches (D2), the inner diameter of the drilling string 180 in inches (D3), a consistency index of the drilling fluid (K_HB) in lb/100 ft²·(s/ft)ⁿ, a dimensionless flow behavior index of the drilling fluid (n_HB), etc. In some implementations, the computer 170 may obtain some of the above parameters via the sensor array 117.

The optimization problem may be formulated as follows:

$${min}_{x} f ( x , y ) \qquad ( Eq . 1 )$$

$$subject to :$$

$${g}_{i} ( x , y ) \leq {C}_{{g}_{i}} ( x , y ) , ∀ i = 1 , … , m \qquad ( Eq . 2 )$$

$${h}_{j} ( x , y ) = {C}_{{h}_{j}} ( x , y ) , ∀ j = 1 , … , p \qquad ( Eq . 3 )$$

$$where ,$$

x∈ [symbol] ⁿ is an n-dimensional vector of the controllable input drilling parameters (e.g., flow in, n∈ [symbol] ); y∈ [symbol] ^{l} is a l-dimensional vector of the measured output parameters (e.g., downhole pressure, l∈ [symbol] ); f(x, y)∈ [symbol] is the objective function to be minimized (e.g., ramp up time of the pump 122); and gᵢ(x, y)≤C_{g}_{ᵢ}(x, y) relates to inequality constraints (e.g., physics-based or data-driven algorithm that evaluates the allowable window of gᵢ(x, y)). The upper bound of the window may be the fracture pressure 206, and the lower bound of the window may be the pore pressure 205. hⱼ(x, y)=Cₕ_{ⱼ}(x, y) relates to equality constraints, where hⱼ(x, y)∈ [symbol] is a sensor measurement such as the initial drilling fluid inflow rate measured by the sensor array 117, and/or a physics-based or data driven algorithm that links the effects of changing flow rate, such as the momentum effect, etc.; m∈ [symbol] is a number of inequality constraints, and p∈ [symbol] is a number of equality constraints. The objective of the optimization problem may be to minimize T-ramp, and this may be subject to both equality and inequality constraints. Flow progresses to block 1204.

At block 1204, the objective function and corresponding constraints are defined by a user and/or the computer 170. For example, the user and/or the computer 170 may generate inputs such as a flow rate trajectory over the ramp-up time (Flow rate vector Q), the time interval(s) for the optimization (time vector t), and other drilling parameters. Flow progresses to block 1206.

At block 1206, the user and/or computer 170 may select an optimization algorithm to perform the optimization. In some implementations, the selected algorithm may be MATLAB's fmincon function, although any other suitable algorithm, solver, approach, computerized functionality, etc. may be used. The objective function may be defined as the function representing the total ramp-up time to be minimized by the optimization algorithm. Initial guesses may be input into the optimization algorithm for decision variables (e.g., flow rates, time intervals, etc.) which may be based on prior knowledge and experience. Choosing the optimization algorithm may also include setting upper and lower bounds for the decision variables, linear and non-linear constraints on the decision variables, and one or more options. In some implementations, the options include optimization settings such as algorithm type, maximum number of function evaluations, etc. Flow progresses to block 1208.

At block 1208, the computer 170 and/or a user provides the inputs from blocks 1202-1206 to the optimization framework 175. The optimization framework 175 may determine an optimal ramp-up time for the pump 122 with respect to the gel effect, momentum effect, viscous effect, delta max ECD constraint, and the defined parameters generated during the optimization problem setup. Flow progresses to block 1210.

At block 1210, the optimization framework 175 obtains and implements the optimized solution at the pump 122. For example, an optimized solution (z-opt) for the pump ramp up trajectory may be output to the pump controller 1115 to alter the flow rate of the drilling fluid. The optimized solution may also include time steps having discrete time intervals for the ramp-up, flow rate values corresponding to the time steps, and other drilling parameters to implement that influence the drilling process. Flow of the flowchart 1200 ceases.

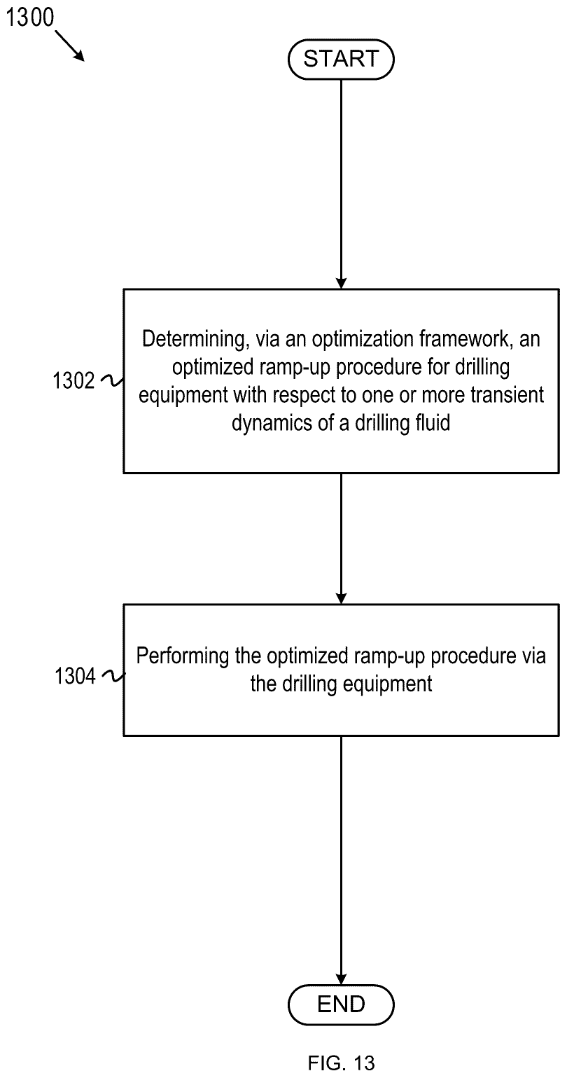

FIG. 13 is a flowchart 1300 depicting a second example method of operations, according to some implementations. Operations of the flowchart 1300 are described with reference to FIGS. 1-12. Operations of the flowchart 1300 begin at block 1302.

At block 1302, the method includes determining, via the optimization framework 175, an optimized ramp-up procedure for drilling equipment with respect to one or more transient dynamics of a drilling fluid. For example, the optimization framework 175 may receive inputs to an optimization problem as described in blocks 1202-1208. The optimization framework may then determine a non-linear ramp up trajectory of the pump 122 via flow rate trajectories such as the flow rate 710 and flow rate 1010 that reduces the ramp-up time while retaining operational safety. This optimization procedure may be automated. Flow progresses to block 1304.

At block 1304, the method includes performing the optimized ramp-up procedure via the drilling equipment. The optimized ramp-up procedure for the pump 122 may be output from the optimization framework 1175 to the pump controller 1115. The pump controller 1115 may be configured to actuate one or more actuators of the pump 122 to achieve the flow rate modulations in accordance with the optimized ramp-up trajectory. For example, the pump controller 1115 may maintain a linear flow rate increase at the pump 122 with respect to the flow rate trajectory 710; when the gel effect subsides after three seconds, the pump controller 1115 may actuate the pump 122 to increase the drilling fluid flow rate non-linearly in accordance with the flow rate trajectory 710. Flow of the flowchart 1300 ceases.

While the aspects of the disclosure are described with reference to various implementations and exploitations, it will be understood that these aspects are illustrative and that the scope of the claims is not limited to them. In general, techniques for pump trajectory optimization during drilling as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

### Alternate Implementations

In some implementations, the optimization algorithm of the optimization framework 175 may be used for monitoring operations. Monitoring the transient dynamic effects (e.g., gel effect, momentum effect, etc.) during drilling may provide valuable insights to field engineers. By carefully observing and analyzing these effects, engineers may be able to make more informed decisions, resulting in safer and more cost-efficient ramp-ups, reducing potential risks, and enhancing overall performance. Comprehensive monitoring and advisory capabilities may contribute to improved drilling practices and outcomes in various applications. This may be performed by field engineers periodically by updating the constraints in the optimization problem of blocks 1202-1206.

While described with regard to conventional drilling practices, the operations described in FIGS. 1-13 may be used for other drilling techniques, such as air drilling, underbalanced drilling, overbalanced drilling, directional drilling, horizontal drilling, rotary drilling, percussion drilling, auger drilling, core drilling, or managed pressure drilling, etc. by modifying the constraints and objectives to account for the specific requirements of these techniques.

As discussed, the optimization algorithm may utilize one or more Navier Stokes equations. In some implementations, the optimization algorithm may be used to model and describe dynamic pressure within the annulus of the wellbore 106. Traditionally, a downhole annulus pressure may be obtained by two ways. First, from the standpipe pressure, hydrostatic pressure, pressure loss at the bit 112 & drill string 180, as depicted in Equation 4:

$${P}_{dh , ann} = {P}_{SPP} + {P}_{hydrostatic} - {P}_{dyn - loss , bit} - {P}_{dyn - loss , drillstring} \qquad ( Eq . 4 )$$

where P_{dh,ann} is the downhole annulus pressure, P_{SPP} is the standpipe pressure, P_{hydrostatic} is the hydrostatic pressure, P_{dyn-loss,bit} is the dynamic pressure loss at the drill bit 112, and P_{dyn-loss,drillstring} is the dynamic pressure loss via the drill string 180.

The drill bit pressure loss may conventionally be difficult to model especially, when a drilling system has mud motors. On the contrary, a second approach only includes hydrostatic pressure and the dynamic pressure of the annulus, as depicted in Equation 5:

$${P}_{dh , ann} = {P}_{hydrostatic} + {P}_{dyn - loss , ann} \qquad ( Eq . 5 )$$

where P_{dyn,ann} is a dynamic pressure loss within the annulus.

In the modelling of the dynamic pressure via the annulus, P_{dyn,ann} the optimization algorithm of the optimization framework 175 may make use of Navier-Stokes equations to describe the dynamic pressure change in the annulus. The dynamic pressure change in the annulus and corresponding Navier-Stokes equations may factor in momentum effects, viscous effects, hydrostatic pressure, a time-dependent gel model, and oscillatory pressure fluctuations known as a Water hammer effect which is the result of a pressure surge or high-pressure shockwave that propagates through a piping system when a fluid in motion is forced to change direction or stop abruptly.

$$\frac{\partial P}{\partial x} = - ρ \frac{\partial V}{\partial t} + μ \frac{{\partial }^{2} V}{\partial {x}^{2}} + ρ g \qquad ( Eq . 6 )$$

Navier-Stokes equations such as Equation 6 above may be used to express the pressure change along the wellbore

$$106 ( \frac{\partial P}{\partial x} ) .$$

The first term,

$$- ρ \frac{\partial V}{\partial t} ,$$

explains the pressure drop due to momentum change. It depends on mud weight ρ, and acceleration of the fluid, ∂V/∂t. The second term,

$$μ \frac{{\partial }^{2} V}{\partial {x}^{2}} ,$$

is the pressure drop due to viscous effects and it depends on viscosity μ. Lastly, the third term, ρg, is the pressure drop because of the hydrostatic effects.

On top of the three main building elements of the Navier-Stokes Equations as depicted above, a transient dynamic gel effect with Mgel may also be introduced to factor in effects from gelation. The effect may be described as a function of gel build time tbuild, shear rate at time instant k−γk, annulus inner and outer diameter Dᵢₙ & Dₒᵤₜ, pipe length L, gel strength calculated at time instant k−τ_{0,k}, and gelation constant z. Therefore, the updated NS-Equations may be written in Equation 7 as:

$$\frac{\partial P}{\partial x} = - ρ \frac{\partial V}{\partial t} + μ \frac{{\partial }^{2} V}{\partial {x}^{2}} + ρ g + {M}_{gel} \qquad ( Eq . 7 )$$

$$where ,$$

$${M}_{gel} = {τ}_{0 , k} * L * \frac{{D}_{in} + {D}_{out}}{( {D}_{in}^{2} - {D}_{out}^{2} )} {e}^{- z * {\int }_{0}^{k} {\dot{γ}}_{k}} \qquad ( Eq . 8 )$$

Unlike constant gel models, the gel model of Equation 8 calculates the shear rate instantaneously with the following relationship in Equation 9:

$${\dot{γ}}_{k} = \frac{16 {Q}_{in}}{π ( {D}_{in}^{2} - {D}_{out}^{2} ) ( {D}_{in} - {D}_{out} )} \qquad ( Eq . 9 )$$

where, Qᵢₙ is the flow passing through annulus.

Furthermore, the momentum effect may be written as:

$$ρ \frac{Δ Q}{Δ t} ,$$

and the viscous effects may be modelled in Equations 10-11 via a Herschel-Bulkley Model as:

$${\dot{γ}}_{k} = 0 , if τ < {τ}_{0} \qquad ( Eq . 10 )$$

$$τ = {τ}_{0} + m {\dot{γ}}_{k}^{n} if τ \geq {τ}_{0} \qquad ( Eq . 11 )$$

where τ is the shear stress in pascals (Pa), τ0 is the yield stress (Pa), γ is the shear rate (s⁻¹), m is the consistency index [Pa sⁿ], and n is the flow index. For the pump startup application, n<1 and hence, the fluid is shear-thinning.

A range of hydraulic models, as seen in Equations 12-14 may be employed to describe the flow dynamics within the well. These models may span from simplified and reduced-order models to more complex and detailed models. The choice of the model may often depend on specific application requirements, where factors such as computational efficiency, desired accuracy, and operational conditions play a pivotal role. Assuming the inflow and outflow rates in the system are consistent (Qᵢₙ=Qₒᵤₜ):
1. Flow in the drill string 180: Given the omission of all phases other than liquid in the wellbore 106, pressure waves may propagate swiftly, simplifying the model to ordinary differential equations (ODEs) instead of partial differential equations (PDEs). The rate of change of mud pump pressure within the drill string 180, from the mud pump 122 to the bit 112, may be expressed in Equation 12 as:

$$\dot{{p}_{p}} = \frac{{β}_{d}}{{V}_{d}} ( {Q}_{pump} - {Q}_{bit} ) \qquad ( Eq . 12 )$$

where,
   \dot{p}ₚ represents the rate of change of the mud pump pressure.
   β_{d} denotes the bulk modulus of the fluid in the drill string 180. The bulk modulus of the fluid quantifies the fluid's resistance to compression. A higher value indicates that the fluid is less compressible.
   V_{d} refers to the volume of the drill string 180. This is a fixed value, representing the internal volume of the pipe from the mud pump 122 to the bit 112.
   Qₚᵤₘₚ is the flow rate of the mud pump 122.
   Q_{bit} is the flow rate at the drill bit 112.
2. Flow in the Annulus: Flow in annulus and other flow rates along with the fluid's Bulk Modulus may be used to describe the rate of change of choke pressure in Equation 13:

$$\dot{{p}_{c}} := \frac{{β}_{a}}{{V}_{a}} ( - \frac{{dV}_{a}}{dt} + {Q}_{bit} + {Q}_{res} - {Q}_{choke} ) \qquad ( Eq . 13 )$$

where,
   \dot{p}_{c} represents the rate of change of the choke pressure.
   βₐ denotes the bulk modulus of the fluid in the annulus.
   dVₐ/dt a denotes the rate of change of the annulus volume. This may account for changes in the wellbore volume due to thermal expansion, equipment movement, or other dynamic factors.
   Q_{bit} represents the flow rate at the drill bit 112.
   Qᵣₑₛ is the flow rate of reservoir fluids into the annulus.
   Q_{choke} indicates the flow rate through the choke, controlling the return flow to the surface 120.
3. Flow through the bit 112 with Gel Effect: The dynamics of flow through the bit 112 may be portrayed in Equation 14:

$$\dot{{q}_{bit}} = \frac{1}{M} ( {p}_{p} - {p}_{c} - F ( {Q}_{bit} ) - Δ ρ {gh}_{TVD} + {F}_{gel} ) \qquad ( Eq . 14 )$$

where,
   p_{c} and pₚ denote the choke and pump 122 pressures, respectively.
   M is the integrated density per cross-section.
   F(Q_{bit}) is a function F that captures frictional pressure as a function of Q_{bit}.
   Δρ=ρₐ−ρ_{d} is the density difference which is typically a small and uncertain parameter related to the amount of cuttings in annulus.
   F_{gel} is the pressure effect due to gelation of the fluid.

Equations 12-14 present an integrated perspective on the hydraulic dynamics inherent to drilling operations. Utilizing the one-phase flow model, the equations offer a streamlined and efficient depiction of flow behaviors, making it especially apt for situations demanding rapid computational outcomes. Additionally, Equation 14 is augmented by incorporating the F_{gel} term, accounting for pressure variations stemming from fluid gelation. This enhancement facilitates the simulation of pressure surges, which may subsequently be harnessed in optimization procedures. In parallel, for a more granular understanding of complex flow scenarios, other models like the multi-phase drift flux models, as previously detailed, may also be implemented in the optimization framework 175.

In some implementations, the optimization framework 175 may streamline the measurement process during optimization (e.g., of block 306) by utilizing standard mud reports generated by commonly used equipment (e.g., the Model 35, a Brookfield viscometer, etc.). These instruments are readily available in the vast majority of drilling applications, making the described optimization approach easily accessible and practical for a wide range of users. By simplifying the measurements and automating critical steps, the optimization approach discussed herein may offer a more user-friendly and efficient approach to drilling operations.

In other implementations, the optimization framework 175 may mitigate the critical reliance on the field experience of an operating team by focusing on lab and on-site measurements. Generating standardization in overcoming transient dynamic stages in drilling operations may reduce human bias in decision-making. By reducing the dependency on subjective judgments and promoting a more data-driven and objective process, the optimization approach contributes to more consistent and reliable outcomes, leading to improved drilling performance and reduced operational risks.

In some implementations, the optimization framework 175 and optimization algorithm may be used for a closed loop control for safer and more robust drilling automation. Model Predictive Control (MPC) may be employed to address the limitations of feedback control and adaptability to real-time changes in the drilling process. MPC is an advanced control strategy that uses a dynamic model of the system to predict its future behavior and computes optimal control actions based on the predicted system response. By incorporating feedback control and optimizing the drilling trajectory over a receding prediction horizon, MPC may continuously adapt to real-time changes in drilling parameters, equipment performance, and environmental conditions, ensuring that the optimized trajectory remains effective and valid as the drilling process evolves.

In the context of drilling operations, MPC may be used to effectively handle the constraints on delta ECD max and other operational constraints while minimizing ramp-up time. By repeatedly solving a constrained optimization problem at each time step, the MPC controller may generate an updated control input sequence that drives the drilling process towards the desired trajectory. Solving the constrained optimization problem at each step may be achieved by continuously repeating the procedure shown in FIG. 12. Repeated optimization may be done within a fixed period of time or time interval, for example, every 1 second, or repeated with a variable time step. This continuous feedback and online optimization process makes the MPC-based approach more robust to uncertainties, disturbances, and changes in the drilling environment. Therefore, employing an MPC-based control strategy may further enhance the performance, safety, and adaptability of the drilling process while also addressing the limitations of the open-loop trajectory optimization approach.

In some implementations, global optimization techniques may be employed to address the limitations of local optimizers, such as the possibility of converging to a local minimum and the dependence on the quality of the initial guess. Global optimization methods aim to find the global minimum of an objective function over a given search space, ensuring a more reliable and robust optimization solution. Some popular global optimization methods include Genetic Algorithms, Particle Swarm Optimization, Simulated Annealing. Differential Evolution, etc. By employing these global optimization techniques, the optimization framework 175 may avoid getting stuck in local minima and relax the dependence on the initial guess for the optimization solution. In doing so, the quality and robustness of the optimization result may be significantly improved, ensuring that the drilling ramp-up trajectory is indeed optimal in the global sense.

Combining global optimization methods with the previously discussed Model Predictive Control (MPC) strategy may further enhance the performance and adaptability of the drilling process, overcoming the limitations of local optimization methods and open-loop trajectory optimization. This may provide a more comprehensive solution for safe and efficient drilling operations, addressing the challenges of uncertainties, disturbances, and changes in the drilling environment.

In some implementations, the optimization framework 175 may be further enhanced by incorporating more advanced models to better represent the drilling process. These advanced models may include additional factors and phenomena beyond the gel effect, momentum effect, viscous effect, hydrostatic pressure, etc. that impact drilling operations, providing a more accurate and comprehensive representation of the process. For instance, the advanced models may consider pressure loss at the drill bit jets, which is an important factor affecting the downhole pressure and drilling efficiency. Additionally, the models may account for the transition from laminar to turbulent flow in the drilling fluid and other rheological phenomena which may have a significant impact on pressure losses and flow behavior. Incorporating temperature effects on fluid properties, as well as on drilling equipment and materials, may also lead to a more accurate representation of the drilling process.

In some implementations, multiphase flow behavior may be incorporated into the advanced models that may be utilized by the optimization framework 175. Multiphase flow takes into account the interactions between different phases of fluids and solid particles present in the drilling process, such as the drilling fluid, gas, and drill cuttings. Understanding and modelling the complex behavior of multiphase flow may significantly improve the accuracy of the optimization process. By considering multiphase flow, the optimization framework 175 may more effectively manage the challenges associated with drilling in environments where gas influx or formation fluid interactions are present. Moreover, accounting for multiphase flow may improve the accuracy of pressure loss calculations, cuttings transport predictions, and hole cleaning efficiency assessments, ultimately leading to a more comprehensive understanding of the drilling process.

Other factors that may be included in the advanced models are the impact of cuttings transport, hole cleaning efficiency, and the influence of drilling tool geometry and configuration on the drilling process. With the integration of these advanced models into the optimization framework 175, the overall drilling process may be better understood and controlled, allowing for more precise and safer optimization of the drilling ramp-up trajectory while taking into account a broader range of factors and drilling conditions affecting the drilling process.

In some implementations, data-driven optimization techniques may be used to address the challenges associated with the fidelity of the models and the reliance on expert knowledge. Data-driven optimization methods may leverage historical and real-time drilling data to develop an understanding of the drilling process and identify optimal ramp-up trajectories, without the need for explicit modelling of the physical phenomena.

These data-driven techniques may include machine learning algorithms, such as supervised learning, unsupervised learning, and reinforcement learning, which may automatically learn complex relationships between the input variables and the desired outcomes. However, other machine learning algorithms may be used. By training these algorithms on large datasets of drilling operations, the models may capture the underlying patterns and relationships that drive the drilling process, thereby reducing the dependence on expert knowledge and detailed physical models.

Using data-driven models within the optimization framework 175 may increase its adaptability to changing drilling conditions and environments. As new data is acquired during the drilling process, such as from the sensor array 117, the models may be updated in real-time to reflect the current state of the system, ensuring that the optimization results remain relevant and accurate.

Some potential data-driven optimization techniques to be used by the optimization framework 175 may include:
i. Regression models, which may predict continuous variables, such as drilling ramp-up time and ECD, based on historical data.
ii. Classification models, which may classify drilling conditions or outcomes into discrete categories, such as safe or unsafe ramp-up trajectories.
iii. Clustering models, which may group similar drilling operations together, enabling the identification of common patterns and trends.
iv. Reinforcement learning algorithms, which may learn optimal drilling policies through trial and error, by interacting with a simulation or the actual drilling environment.

In other implementations, a coordinated control strategy may be developed with Managed Pressure Drilling (MPD) that focuses on the global benefits of drilling operations. MPD is a drilling technique that precisely controls the annular pressure profile in the wellbore by manipulating the choke, which adjusts the backpressure applied at the surface. By integrating the ramp-up optimization process with MPD, the computer 170 may assist in developing the optimization framework 175 into a multi-objective optimization framework that controls not only the choke but also the pump and other drilling parameters, leading to a more comprehensive and efficient drilling process.

The coordinated control strategy with MPD may involve the following key elements:
i. Multi-objective optimization: The optimization framework 175 may consider multiple objectives simultaneously, such as minimizing ramp-up time, maintaining the desired ECD, and ensuring efficient hole cleaning. By balancing these competing objectives, the coordinated control strategy may provide a more globally optimal solution that considers various aspects of the drilling process.
ii. Coordinated control of choke and pump: The optimization framework 175 may jointly control the choke, pump 122, and other drilling parameters in a coordinated manner. This integrated approach enables better management of the downhole pressure and flow conditions, leading to improved safety and efficiency in drilling operations.
iii. Adaptive and robust control: The coordinated control strategy may adapt to changes in drilling conditions and environments by continuously updating the optimization parameters based on real-time data. This adaptive control approach ensures that the optimization results remain relevant and accurate, even in the face of uncertainties and variations in drilling conditions.
iv. Integration with MPD technologies: The coordinated control strategy may be seamlessly integrated with existing MPD technologies, such as Rotating Control Devices (RCDs), Non-Return Valves (NRVs), and intelligent chokes. This integration allows for better management of the annular pressure profile and a more comprehensive approach to drilling optimization.

This approach may also be integrated with MPD controllers by providing setpoints to MPD controllers. For example, the optimization problem of FIG. 12 may also provide a downhole ECD setpoint and allow the MPD controller (integrated with the pump controller 1115) to adjust surface equipment of FIG. 1 to achieve the given ECD setpoint. By implementing a coordinated control strategy with MPD, the ramp-up optimization process may be enhanced to provide more globally optimal solutions that consider multiple objectives and control variables.

### EXAMPLE IMPLEMENTATIONS

Implementation #1: A method for minimizing a ramp-up time of drilling equipment used to drill a wellbore through a subsurface formation, the method comprising: determining, via an optimization framework, an optimized ramp-up procedure for the drilling equipment with respect to one or more transient dynamics of a drilling fluid; and performing the optimized ramp-up procedure via the drilling equipment.

Implementation #2: The method of Implementation 1, wherein performing the optimized ramp-up procedure via the drilling equipment comprises altering a flow rate of the drilling fluid according to the optimized ramp-up procedure.

Implementation #3: The method of any one or more of Implementations 1 or 2, wherein the one or more transient dynamics of the drilling fluid comprise a gel effect, a viscous effect, a momentum effect, and a hydrostatic pressure of the drilling fluid.

Implementation #4: The method of any one or more of Implementations 1-3, further comprising: modeling, via the optimization framework, a shear rate of the drilling fluid with respect to the gel effect and the viscous effect.

Implementation #5: The method of any one or more of Implementations 1-4, wherein the drilling equipment includes a mud pump configured to pump the drilling fluid into the wellbore.

Implementation #6: The method of any one or more of Implementations 1-5, further comprising: defining a drilling window including a pore pressure of the subsurface formation, a fracture pressure of the subsurface formation, and a maximum equivalent circulating density of the drilling fluid; defining one or more properties of the drilling fluid; and generating, via the optimization framework, a non-linear ramp-up trajectory for the drilling equipment that does not exceed the drilling window.

Implementation #7: The method of any one or more of Implementations 1-6, further comprising: outputting, via the optimization framework, a plurality of time steps to an equipment actuation system; and actuating the drilling equipment to perform the optimized ramp-up procedure at the plurality of time steps.

Implementation #8: A system configured to minimize a ramp-up time of drilling equipment used to drill a wellbore through a subsurface formation, the system comprising: a drill string consisting of one or more pipes; a drill bit coupled to the drill string; a processor; and a computer-readable medium having instructions executable by the processor, the instructions including: instructions to determine, via an optimization framework, an optimized ramp-up procedure for the drilling equipment with respect to one or more transient dynamics of a drilling fluid; and instructions to perform the optimized ramp-up procedure via the drilling equipment.

Implementation #9: The system of Implementation 8, wherein the instructions to perform the optimized ramp-up procedure via the drilling equipment comprise instructions to alter a flow rate of the drilling fluid according to the optimized ramp-up procedure.

Implementation #10: The system of any one or more of Implementations 8 or 9, wherein the one or more transient dynamics of the drilling fluid comprise a gel effect, a viscous effect, a momentum effect, and a hydrostatic pressure of the drilling fluid.

Implementation #11: The system of any one or more of Implementations 8-10, further comprising: instructions to model, via the optimization framework, a shear rate of the drilling fluid with respect to the gel effect and the viscous effect.

Implementation #12: The system of any one or more of Implementations 8-11, wherein the drilling equipment includes a mud pump configured to pump the drilling fluid into the wellbore.

Implementation #13: The system of any one or more of Implementations 8-12, further comprising: instructions to define a drilling window including a pore pressure of the subsurface formation, a fracture pressure of the subsurface formation, and a maximum equivalent circulating density of the drilling fluid; instructions to define one or more properties of the drilling fluid; and instructions to generate, via the optimization framework, a non-linear ramp-up trajectory for the drilling equipment that does not exceed the drilling window.

Implementation #14: The system of any one or more of Implementations 8-13, further comprising: instructions to output, via the optimization framework, a plurality of time steps to an equipment actuation system; and instructions to actuate the drilling equipment to perform the optimized ramp-up procedure at the plurality of time steps.

Implementation #15: One or more non-transitory machine-readable media including instructions executable by a processor to cause the processor to minimize a ramp-up time of drilling equipment used to drill a wellbore through a subsurface formation, the instructions comprising: instructions to determine, via an optimization framework, an optimized ramp-up procedure for the drilling equipment with respect to one or more transient dynamics of a drilling fluid; and instructions to perform the optimized ramp-up procedure via the drilling equipment.

Implementation #16: The machine-readable media of Implementation 15, wherein the instructions to perform the optimized ramp-up procedure via the drilling equipment comprise instructions to alter a flow rate of the drilling fluid according to the optimized ramp-up procedure.

Implementation #17: The machine-readable media of any one or more of Implementations 15 or 16, wherein the one or more transient dynamics of the drilling fluid comprise a gel effect, a viscous effect, a momentum effect, and a hydrostatic pressure of the drilling fluid.

Implementation #18: The machine-readable media of any one or more of Implementations 15-17, further comprising: instructions to model, via the optimization framework, a shear rate of the drilling fluid with respect to the gel effect and the viscous effect.

Implementation #19: The machine-readable media of any one or more of Implementations 15-18, further comprising: instructions to define a drilling window including a pore pressure of the subsurface formation, a fracture pressure of the subsurface formation, and a maximum equivalent circulating density of the drilling fluid; instructions to define one or more properties of the drilling fluid; and instructions to generate, via the optimization framework, a non-linear ramp-up trajectory for the drilling equipment that does not exceed the drilling window, wherein the drilling equipment includes a mud pump configured to pump the drilling fluid into the wellbore.

Implementation #20: The machine-readable media of any one or more of Implementations 15-19, further comprising: instructions to output, via the optimization framework, a plurality of time steps to an equipment actuation system; and instructions to actuate the drilling equipment to perform the optimized ramp-up procedure at the plurality of time steps.

The various illustrative logics, logical blocks, modules, circuits, and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described throughout. Whether such functionality is implemented in hardware or software depends upon the particular application and design constraints imposed on the overall system.

The hardware and data processing apparatus used to implement the various illustrative logics, logical blocks, modules and circuits described in connection with the implementations disclosed herein may be implemented or performed with a general purpose single- or multi-chip processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described herein. A general-purpose processor may be a microprocessor or any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more implementations, the functions and/or functionalities described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, e.g., one or more modules of computer program instructions stored on a computer storage media for execution by, or to control the operation of, a computing device.

If implemented in software, the functions and/or functionalities may be stored on or transmitted over as one or more instructions or code on a computer-readable medium. The processes of a method or algorithm disclosed herein may be implemented in a processor-executable instructions which may reside on a computer-readable medium. Computer-readable media includes both computer storage media and communication media including any medium that may be enabled to transfer a computer program from one place to another. Storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-Ray™ disc where disks usually reproduce data magnetically, while discs reproduce data optically with lasers. Combinations also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein but are to be accorded the widest scope consistent with this disclosure, the principles and the novel features disclosed herein.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described as acting in certain combinations and even initially claimed as such, one or more features from a claimed combination may in some cases be excised from the combination, and the claimed combination may be directed to a subcombination or variation of a subcombination.

While operations are depicted in the drawings in a particular order, this should not be understood as requiring that such operations be performed in the particular order shown or in sequential order, or that all illustrated operations be performed, to achieve desirable results. Further, the drawings may schematically depict one more example process in the form of a flow diagram. However, some operations may be omitted and/or other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described should not be understood as requiring such separation in all implementations, and the described program components and systems may generally be integrated together in a single software product or packaged into multiple software products. Additionally, other implementations are within the scope of the following claims. In some cases, the actions recited in the claims may be performed in a different order and still achieve desirable results.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” may be infringed with only one of the listed items, multiple of the listed items, and one or more of the items in the list and another item not listed. As used herein, a phrase referring to “at least one of” a list of items refers to any combination of those items, including single members. As an example, “at least one of: a, b, or c” is intended to cover: a, b, c, a-b, a-c, b-c, and a-b-c.

As used herein, the term “or” is inclusive unless otherwise explicitly noted. Thus, the phrase “at least one of A, B, or C” is satisfied by any element from the set {A, B, C} or any combination thereof, including multiples of any element.

1. A method for minimizing a ramp-up time of drilling equipment used to drill a wellbore through a subsurface formation, the method comprising:
determining, via an optimization framework, an optimized ramp-up procedure for the drilling equipment with respect to one or more transient dynamics of a drilling fluid; and
performing the optimized ramp-up procedure via the drilling equipment.

2. The method of claim 1, wherein performing the optimized ramp-up procedure via the drilling equipment comprises altering a flow rate of the drilling fluid according to the optimized ramp-up procedure.

3. The method of claim 1, wherein the one or more transient dynamics of the drilling fluid comprise a gel effect, a viscous effect, a momentum effect, and a hydrostatic pressure of the drilling fluid.

4. The method of claim 3, further comprising:
modeling, via the optimization framework, a shear rate of the drilling fluid with respect to the gel effect and the viscous effect.

5. The method of claim 1, wherein the drilling equipment includes a mud pump configured to pump the drilling fluid into the wellbore.

6. The method of claim 1, further comprising:
defining a drilling window including a pore pressure of the subsurface formation, a fracture pressure of the subsurface formation, and a maximum equivalent circulating density of the drilling fluid;
defining one or more properties of the drilling fluid; and
generating, via the optimization framework, a non-linear ramp-up trajectory for the drilling equipment that does not exceed the drilling window.

7. The method of claim 6, further comprising:
outputting, via the optimization framework, a plurality of time steps to an equipment actuation system; and
actuating the drilling equipment to perform the optimized ramp-up procedure at the plurality of time steps.

8. A system configured to minimize a ramp-up time of drilling equipment used to drill a wellbore through a subsurface formation, the system comprising:
a drill string consisting of one or more pipes;
a drill bit coupled to the drill string;
a processor; and
a computer-readable medium having instructions executable by the processor, the instructions including:
instructions to determine, via an optimization framework, an optimized ramp-up procedure for the drilling equipment with respect to one or more transient dynamics of a drilling fluid; and
instructions to perform the optimized ramp-up procedure via the drilling equipment.

9. The system of claim 8, wherein the instructions to perform the optimized ramp-up procedure via the drilling equipment comprise instructions to alter a flow rate of the drilling fluid according to the optimized ramp-up procedure.

10. The system of claim 8, wherein the one or more transient dynamics of the drilling fluid comprise a gel effect, a viscous effect, a momentum effect, and a hydrostatic pressure of the drilling fluid.

11. The system of claim 10, further comprising:
instructions to model, via the optimization framework, a shear rate of the drilling fluid with respect to the gel effect and the viscous effect.

12. The system of claim 8, wherein the drilling equipment includes a mud pump configured to pump the drilling fluid into the wellbore.

13. The system of claim 8, further comprising:
instructions to define a drilling window including a pore pressure of the subsurface formation, a fracture pressure of the subsurface formation, and a maximum equivalent circulating density of the drilling fluid;
instructions to define one or more properties of the drilling fluid; and
instructions to generate, via the optimization framework, a non-linear ramp-up trajectory for the drilling equipment that does not exceed the drilling window.

14. The system of claim 13, further comprising:
instructions to output, via the optimization framework, a plurality of time steps to an equipment actuation system; and
instructions to actuate the drilling equipment to perform the optimized ramp-up procedure at the plurality of time steps.

15. One or more non-transitory machine-readable media including instructions executable by a processor to cause the processor to minimize a ramp-up time of drilling equipment used to drill a wellbore through a subsurface formation, the instructions comprising:
instructions to determine, via an optimization framework, an optimized ramp-up procedure for the drilling equipment with respect to one or more transient dynamics of a drilling fluid; and
instructions to perform the optimized ramp-up procedure via the drilling equipment.

16. The machine-readable media of claim 15, wherein the instructions to perform the optimized ramp-up procedure via the drilling equipment comprise instructions to alter a flow rate of the drilling fluid according to the optimized ramp-up procedure.

17. The machine-readable media of claim 15, wherein the one or more transient dynamics of the drilling fluid comprise a gel effect, a viscous effect, a momentum effect, and a hydrostatic pressure of the drilling fluid.

18. The machine-readable media of claim 17, further comprising:
instructions to model, via the optimization framework, a shear rate of the drilling fluid with respect to the gel effect and the viscous effect.

19. The machine-readable media of claim 15, further comprising:
instructions to define a drilling window including a pore pressure of the subsurface formation, a fracture pressure of the subsurface formation, and a maximum equivalent circulating density of the drilling fluid;
instructions to define one or more properties of the drilling fluid; and
instructions to generate, via the optimization framework, a non-linear ramp-up trajectory for the drilling equipment that does not exceed the drilling window,
wherein the drilling equipment includes a mud pump configured to pump the drilling fluid into the wellbore.

20. The machine-readable media of claim 19, further comprising:
instructions to output, via the optimization framework, a plurality of time steps to an equipment actuation system; and
instructions to actuate the drilling equipment to perform the optimized ramp-up procedure at the plurality of time steps.
